(19) United States
(12) Patent Application Publication
(10) Pub. No.: US 2025/0203921 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventors: Yotaro GOTO, Tokyo (JP); Atsushi SAKAI, Tokyo (JP); Katsumi EIKYU, Tokyo (JP)

(21) Appl. No.: 18/915,760

(22) Filed: Oct. 15, 2024

(30) Foreign Application Priority Data
Dec. 18, 2023 (JP) 2023-213010

(51) Int. Cl. H01L 29/78; H01L 21/265; H01L 21/266; H01L 29/06; H01L 29/08; H01L 29/66

(52) U.S. Cl. CPC H10D 30/65; H01L 21/26513; H01L 21/26586; H01L 21/266; H10D 30/0281; H10D 62/109; H10D 62/153

(57) ABSTRACT

An n-type drift region and a p-type well region are formed in a semiconductor substrate. An n-type first drain region and an n-type second drain region are formed in the n-type drift region, and an n-type source region and an n-type semiconductor region are formed in the p-type well region. An impurity concentration of the n-type semiconductor region is lower than an impurity concentration of the n-type source region. A gate electrode includes an n-type first gate electrode portion and an n-type second gate electrode portion extending in the Y direction, and a p-type gate connection portion connecting the first gate electrode portion and the second gate electrode portion. In plan view, the n-type source region is arranged between the first gate electrode portion and the second gate electrode portion.

### CROSS-REFERENCE TO RELATED APPLICATIONS

The disclosure of Japanese Patent Application No. 2023-213010 filed on Dec. 18, 2023, including the specification, drawings and abstract is incorporated herein by reference in its entirety.

### BACKGROUND

The present invention relates to a semiconductor device and a method of manufacturing the same, and can be suitably used, for example, for a semiconductor device having a MOSFET and a method of manufacturing the same.

In power conversion circuits such as inverter circuits, for example, power switching elements such as Laterally Diffused Metal-Oxide-Semiconductor Field Effect Transistors (LDMOSFETs) are used. The power switching elements are formed over a semiconductor substrate.

There are disclosed techniques listed below.
[Patent Document 1] Japanese Unexamined Patent Application Publication No. 2019-46875

Patent Document 1 discloses a technique related to a semiconductor device having LDMOSFETs.

### SUMMARY

It is desired to improve the performance of semiconductor devices having MOSFETs.

Other objects and novel features will become apparent from the description of this specification and the accompanying drawings.

According to one embodiment, a semiconductor device includes a gate electrode formed over a main surface of a semiconductor substrate via a gate dielectric film, a drift region of a first conductivity type and a well region of a second conductivity type formed in the semiconductor substrate, and a first drain region of the first conductivity type and a second drain region formed in the drift region. The semiconductor device further includes a source region of the first conductivity type and an LDD region formed in the well region. The gate electrode includes a first gate electrode portion of the first conductivity type and a second gate electrode portion extending in a first direction, and a gate connection portion of the second conductivity type connecting the first gate electrode portion and the second gate electrode portion. In plan view, a part of the first gate electrode portion, a part of the second gate electrode portion, and a part of the gate connection portion overlap the well region, and another part of the first gate electrode portion, another part of the second gate electrode portion, and another part of the gate connection portion overlap the drift region. In plan view, the LDD region is formed along the first gate electrode portion, the gate connection portion, and the second gate electrode portion.

According to one embodiment, the performance of the semiconductor device can be improved.

### BRIEF DESCRIPTION OF THE DRAWINGS

FIG. 1 is a main portion cross-sectional view of a semiconductor device according to a first embodiment.

FIG. 2 is a main portion cross-sectional view of the semiconductor device according to the first embodiment.

FIG. 3 is a main portion cross-sectional view of the semiconductor device according to the first embodiment.

FIG. 4 is a main portion plan view of the semiconductor device according to the first embodiment.

FIG. 5 is a main portion plan view of the semiconductor device according to the first embodiment.

FIG. 6 is a main portion plan view of the semiconductor device according to the first embodiment.

FIG. 7 is a main portion cross-sectional view during a manufacturing step of the semiconductor device according to the first embodiment.

FIG. 8 is a main portion cross-sectional view during the manufacturing step of the semiconductor device following FIG. 7.

FIG. 9 is a main portion cross-sectional view during the manufacturing step of the semiconductor device as in FIG. 8.

FIG. 10 is a main portion cross-sectional view during the manufacturing step of the semiconductor device following FIG. 8.

FIG. 11 is a main portion cross-sectional view during the manufacturing step of the semiconductor device as in FIG. 10.

FIG. 12 is a main portion cross-sectional view during the manufacturing step of the semiconductor device following FIG. 10.

FIG. 13 is a main portion cross-sectional view during the manufacturing step of the semiconductor device as in FIG. 12.

FIG. 14 is a main portion plan view during the manufacturing step of the semiconductor device following FIG. 10.

FIG. 15 is a main portion cross-sectional view during the manufacturing step of the semiconductor device following FIG. 12.

FIG. 16 is a main portion cross-sectional view during the manufacturing step of the semiconductor device as in FIG. 15.

FIG. 17 is a main portion cross-sectional view during the manufacturing step of the semiconductor device following FIG. 15.

FIG. 18 is a main portion cross-sectional view during the manufacturing step of the semiconductor device as in FIG. 17.

FIG. 19 is a main portion cross-sectional view during the manufacturing step of the semiconductor device following FIG. 17.

FIG. 20 is a main portion cross-sectional view during the manufacturing step of the semiconductor device as in FIG. 19.

FIG. 21 is a main portion cross-sectional view during the manufacturing step of the semiconductor device following FIG. 19.

FIG. 22 is a main portion cross-sectional view during the manufacturing step of the semiconductor device as in FIG. 21.

FIG. 23 is a main portion cross-sectional view during the manufacturing step of the semiconductor device following FIG. 21.

FIG. 24 is a main portion cross-sectional view during the manufacturing step of the semiconductor device as in FIG. 23.

FIG. 25 is a main portion cross-sectional view during the manufacturing step of the semiconductor device following FIG. 23.

FIG. 26 is a main portion cross-sectional view during the manufacturing step of the semiconductor device as in FIG. 25.

FIG. 27 is a main portion cross-sectional view during the manufacturing step of the semiconductor device following FIG. 25.

FIG. 28 is a main portion cross-sectional view during the manufacturing step of the semiconductor device as in FIG. 27.

FIG. 29 is an explanatory diagram for explaining the issues of an examined example.

FIG. 30 is an explanatory diagram for explaining the issues of the examined example.

FIG. 31 is a main portion cross-sectional view during a manufacturing step of a semiconductor device according to a second embodiment.

FIG. 32 is a main portion plan view during a manufacturing step of the semiconductor device according to the second embodiment.

### DETAILED DESCRIPTION

In the following embodiments, for convenience, when necessary, they are explained by dividing into multiple sections or embodiments; except where specifically indicated, they are not unrelated to each other, and one may be related to the other as a part or all of a modified example, detail, supplementary explanation, etc. Furthermore, in the following embodiments, when referring to the number of elements, etc. (including the number of elements, numerical values, quantities, ranges, etc.), it is not limited to the specific number, but may be not less than or equal to the specific number, except for cases where the number is specifically indicated and is clearly limited to the specific number in principle. Moreover, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of plan view, hatching may be used to make the drawing easier to see.

Furthermore, a plan view corresponds to the case when viewed from a plane substantially parallel to the main surface or the back surface of a semiconductor substrate SB. The bottom surface and the lower surface mean the same thing. The height position corresponds to the distance from the back surface of the semiconductor substrate SB. The depth position corresponds to the distance from the main surface of the semiconductor substrate SB.

Furthermore, in the present application, a MOSFET (Metal Oxide Semiconductor Field Effect Transistor) or an LDMOSFET (Laterally Diffused Metal Oxide Semiconductor Field Effect Transistor) includes not only MOSFETs employing an oxide film as a gate dielectric film but also MOSFETs employing dielectric films other than oxide films as the gate dielectric film. Additionally, LDMOSFET may also be referred to as HV-MOSFET (High Voltage Metal Oxide Semiconductor Field Effect Transistor) or DEMOSFET (Drain Extended Metal Oxide Semiconductor Field Effect Transistor).

Moreover, an n-channel type MOSFET can be considered as an n-type MOSFET, and a p-channel type MOSFET can be considered as a p-type MOSFET. In this context, n-type means that the conductivity type of the channel during the on-state is n-type, and p-type means that the conductivity type of the channel during the on-state is p-type.

### First Embodiment

### Structure of Semiconductor Device

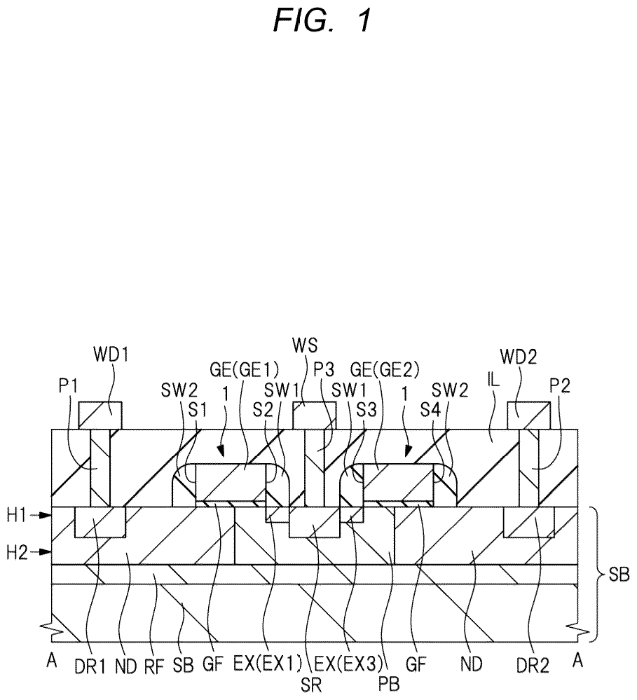

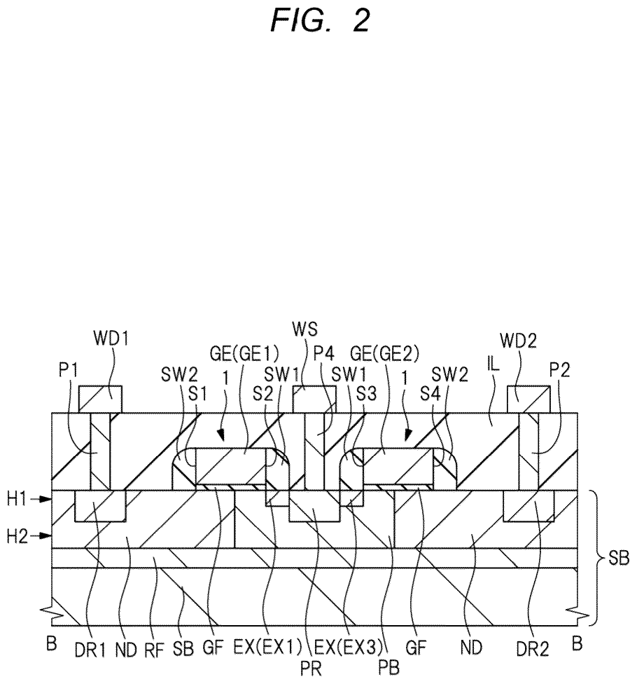

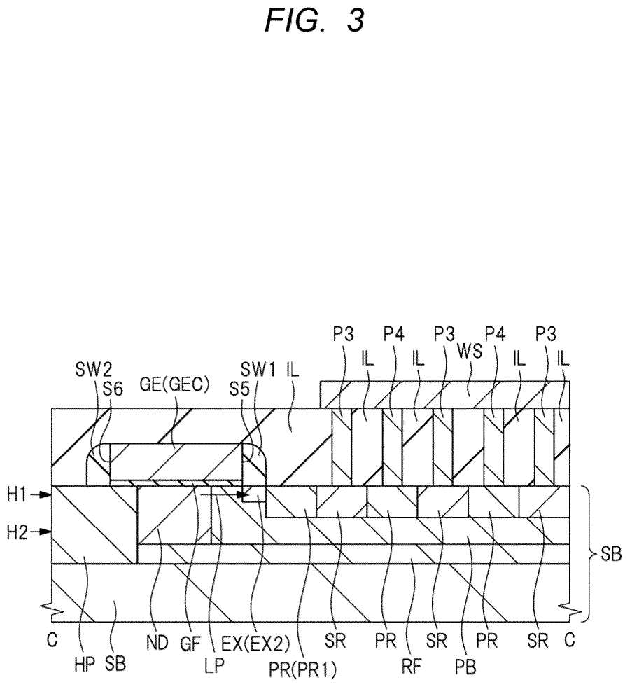

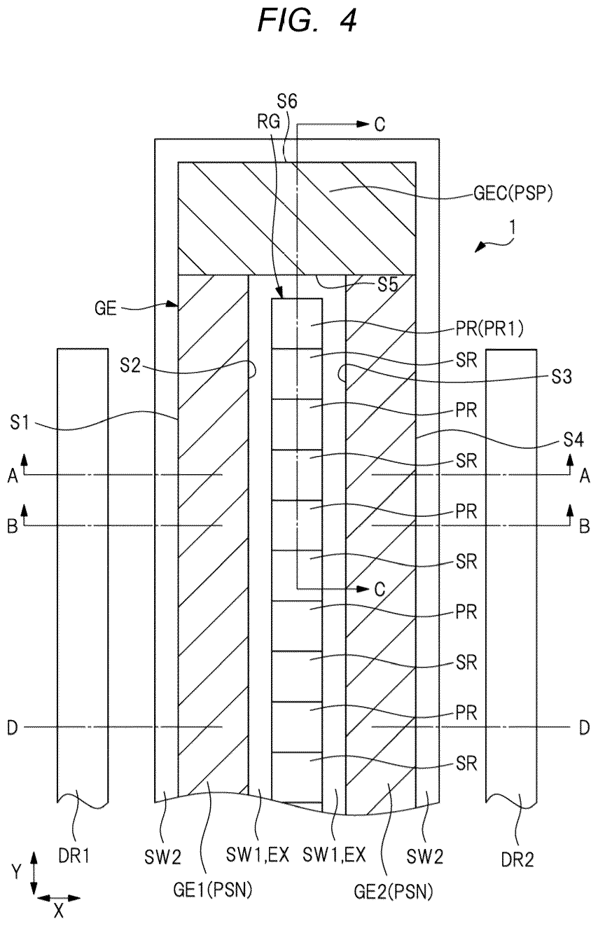

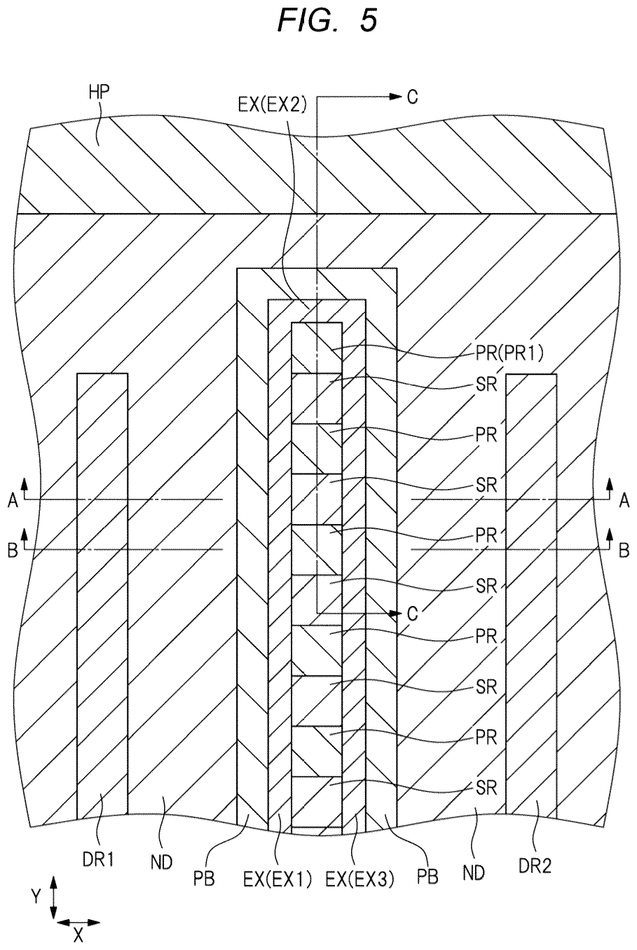

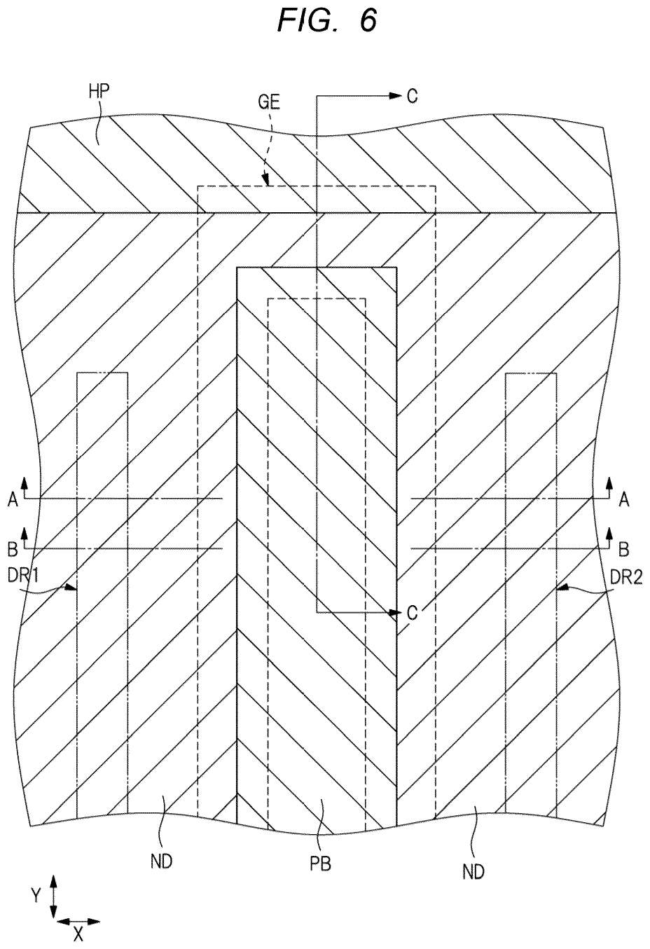

FIGS. 1 to 3 show cross-sectional views orthogonal to the main surface of the semiconductor substrate SB. FIGS. 4 to 6 show plan views parallel to the main surface of the semiconductor substrate SB. The planar regions shown in FIGS. 4, 5, and 6 are identical to each other. The cross-sectional views along line A-A in FIGS. 4 to 6 correspond to FIG. 1, the cross-sectional views along line B-B in FIGS. 4 to 6 correspond to FIG. 2, and the cross-sectional views along line C-C in FIGS. 4 to 6 correspond to FIG. 3. Although FIG. 4 is a plan view, in FIG. 4, a gate electrode GE is hatched. FIG. 5 is a plan view at the height position H1 shown in FIGS. 1 to 3. FIG. 6 is a plan view at the height position H2 shown in FIGS. 1 to 3. In FIG. 6, the planar position of the gate electrode GE is indicated by a dotted line, and the planar positions of an n-type drain region DR1 and an n-type drain region DR2 are indicated by dash-dotted lines.

The semiconductor device of the present first embodiment includes a power switching element used in a power conversion circuit such as inverter circuit, and herein, the transistor configuring the power switching element is an LDMOSFET.

As shown in FIGS. 1 to 6, the semiconductor device of the present first embodiment includes the semiconductor substrate SB, an LDMOSFET 1 formed over the main surface of the semiconductor substrate SB, and a dielectric film IL formed over the main surface of the semiconductor substrate SB.

The semiconductor substrate SB may be made of, for example, p-type single-crystal silicon into which p-type impurities such as boron (B) have been introduced.

The semiconductor substrate SB may use an epitaxial wafer. In this case, the semiconductor substrate SB includes a p-type substrate body made of, for example, a single-crystal silicon substrate, and a p-type semiconductor layer formed over the p-type substrate body by epitaxial growth. The main surface of the semiconductor substrate SB is formed by the main surface of the p-type semiconductor layer. In FIGS. 1 to 3, a structure including the p-type substrate body and the p-type semiconductor layer is shown as the semiconductor substrate SB. An n-type buried layer may be formed in the upper part of the p-type substrate body, and a p-type semiconductor layer may be formed over the n-type buried layer.

The LDMOSFET 1 is an n-type (n-channel) LDMOSFET.

The LDMOSFET 1 includes a p-type well region PB, an n-type drift region ND, the n-type drain region DR1, the n-type drain region DR2, an n-type semiconductor region EX, a plurality of n-type source regions SR, the plurality of p-type semiconductor regions PR, a p-type resurf region RF, a p-type semiconductor region HP, a gate dielectric film GF, and the gate electrode GE.

The p-type well region PB, the n-type drift region ND, the n-type drain region DR1, the n-type drain region DR2, the n-type semiconductor region EX, the plurality of n-type source regions SR, the plurality of p-type semiconductor regions PR, the p-type resurf region RF, and the p-type semiconductor region HP are formed in the semiconductor substrate SB. The gate electrode GE is formed over the main surface of the semiconductor substrate SB via the gate dielectric film GF. The dielectric film IL is formed over the main surface of the semiconductor substrate SB so as to cover the LDMOSFET 1.

The gate electrode GE includes a gate electrode portion GE1, a gate electrode portion GE2, and a gate connection portion GEC that connects the gate electrode portion GE1 and the gate electrode portion GE2. The gate connection portion GEC, the gate electrode portion GE1 and the gate electrode portion GE2 are integrally formed.

The gate electrode portion GE1 and the gate electrode portion GE2 extend in the Y direction, respectively. The gate electrode portion GE1 and the gate electrode portion GE2 are spaced apart from each other in the X direction. One end of the gate electrode portion GE1 in the Y direction and one end of the gate electrode portion GE2 in the Y direction are connected to the gate connection portion GEC extending in the X direction.

Although not shown in FIG. 4, the other end of the gate electrode portion GE1 in the Y direction and the other end of the gate electrode portion GE2 in the Y direction are connected to a gate connection portion similar to the gate connection portion GEC. The structure of the semiconductor substrate SB under that gate connection portion is similar to the structure of the semiconductor substrate SB under the gate connection portion GEC. The LDMOSFET 1 has a symmetrical structure with respect to the D-D line shown in FIG. 4.

Here, the Y direction corresponds to the gate width direction of each of the gate electrode portion GE1 and the gate electrode portion GE2. The X direction corresponds to the gate length direction of each of the gate electrode portion GEL and the gate electrode portion GE2. The X direction and the Y direction intersect each other and are preferably orthogonal to each other. Each of the X direction and the Y direction is parallel to the main surface of the semiconductor substrate SB.

As shown in FIG. 4, the gate electrode portion GEL includes a side surface S1 and a side surface S2 opposite the side surface S1. The side surface S1 and the side surface S2 are substantially parallel to each other in the Y direction. The gate electrode portion GE2 includes a side surface S3 and a side surface S4 opposite the side surface S3. The side surface S3 and the side surface S4 are substantially parallel to each other in the Y direction. The gate connection portion GEC includes a side surface S5 and a side surface S6 opposite the side surface S5. The side surface S5 and the side surface S6 are substantially parallel to each other in the X direction. The side surface S2, the side surface S3, and the side surface S5 are inner peripheral side surfaces of the gate electrode GE, and the side surface S1, the side surface S4, and the side surface S6 are outer peripheral side surfaces of the gate electrode GE. The side surface S2 of the gate electrode portion GE1 and the side surface S3 of the gate electrode portion GE2 face each other in the X direction. The side surface S5 of the gate connection portion GEC intersects with the side surface S2 of the gate electrode portion GE1 and the side surface S3 of the gate electrode portion GE2.

As shown in FIGS. 1 to 4, a sidewall spacer (sidewall dielectric film) SW1 formed of a dielectric film is formed on the inner peripheral side surface of the gate electrode GE. A sidewall spacer (sidewall dielectric film) SW2 formed of the dielectric film is formed on the outer peripheral side surface of the gate electrode GE. Therefore, the sidewall spacer SW1 is formed on the side surface S2 of the gate electrode portion GE1, on the side surface S3 of the gate electrode portion GE2, and on the side surface S5 of the gate connection portion GEC. The sidewall spacer SW2 is formed on the side surface S1 of the gate electrode portion GE1, on the side surface S4 of the gate electrode portion GE2, and on the side surface S6 of the gate connection portion GEC.

As shown in FIGS. 1 to 3, the p-type well region (p-type semiconductor region) PB and the n-type drift region (n-type semiconductor region) ND are formed in the upper part of the semiconductor substrate SB. In the case of FIGS. 1 to 3, the p-type resurf region (p-type semiconductor region) RF is formed under a bottom surface of the n-type drift region ND and a bottom surface of the p-type well region PB. A p-type impurity concentration of the p-type resurf region RF is higher than a p-type impurity concentration of the semiconductor substrate SB. It is possible not to form the p-type resurf region RF. In the case of FIG. 3, the p-type semiconductor region HP is formed under the gate connection portion GEC. A p-type impurity concentration of the p-type semiconductor region HP is higher than the p-type impurity concentration of the semiconductor substrate SB. It is possible not to form the p-type semiconductor region HP.

As shown in FIGS. 4 and 6, in plan view, the p-type well region PB is formed to include the region between the gate electrode portion GE1 and the gate electrode portion GE2. In plan view, the p-type well region PB is surrounded by the n-type drift region ND. In plan view, a part of the gate electrode portion GE1, a part of the gate electrode portion GE2, and a part of the gate connection portion GEC overlap the p-type well region PB, and another part of the gate electrode portion GE1, another part of the gate electrode portion GE2, and another part of the gate connection portion GEC overlap the n-type drift region ND.

A part of the p-type well region PB is located under the gate electrode portion GE1, another part of the p-type well region PB is located under the gate electrode portion GE2, and yet another part of the p-type well region PB is located under the gate connection portion GEC. A part of the n-type drift region ND is located under the gate electrode portion GE1, another part of the n-type drift region ND is located under the gate electrode portion GE2, and yet another part of the n-type drift region ND is located under the gate connection portion GEC.

As shown in FIGS. 1, 2, and 6, under the gate electrode portion GE1, the n-type drift region ND and the p-type well region PB are adjacent to each other in the X direction. Under the gate electrode portion GE2, the n-type drift region ND and the p-type well region PB are adjacent to each other in the X direction. As shown in FIGS. 3 and 6, under the gate connection portion GEC, the n-type drift region ND and the p-type well region PB are adjacent to each other in the Y direction.

A PN junction is formed at the boundary between the p-type well region PB and the n-type drift region ND. The boundary between the p-type well region PB and the n-type drift region ND extends in the Y direction under the gate electrode portion GE1, extends in the X direction under the gate connection portion GEC, and extends in the Y direction under the gate electrode portion GE2.

As shown in FIGS. 1 to 3, the plurality of n-type source regions (n-type semiconductor regions) SR and the plurality of p-type semiconductor regions PR are formed in the p-type well region PB. The p-type impurity concentration of each of the plurality of p-type semiconductor regions PR is higher than the p-type impurity concentration of the p-type well region PB. The p-type impurity concentration of the p-type well region PB is higher than the p-type impurity concentration of the semiconductor substrate SB. The upper surface of each of the plurality of n-type source regions SR and the upper surface of each of the plurality of p-type semiconductor regions PR reach the main surface of the semiconductor substrate SB. The bottom surface of each of the plurality of n-type source regions SR and the bottom surface of each of the plurality of p-type semiconductor regions PR are shallower than the bottom surface of the p-type well region PB.

As shown in FIG. 4, in plan view, the plurality of n-type source regions SR and the plurality of p-type semiconductor regions PR are aligned in a row in the Y direction in the region surrounded by the gate electrode GE. In plan view, the p-type semiconductor regions PR and the n-type source regions SR are alternately arranged in the Y direction between the gate electrode portion GE1 and the gate electrode portion GE2. A PN junction is formed at the boundary between the n-type source e regions SR and the p-type semiconductor regions PR that are adjacent in the Y direction. The plurality of n-type source regions SR and the plurality of p-type semiconductor regions PR arranged in the Y direction configure an array region RG. At both ends of the array region RG in the Y direction, the p-type semiconductor regions PR, not the n-type source regions SR, respectively are arranged. A p-type semiconductor region PR arranged at the end of the array region RG in the Y direction is referred to as the p-type semiconductor region PR1. In plan view, the array region RG is surrounded by the gate electrode GE.

The p-type well region PB can function as a back gate. The p-type well region PB can also function as a punch-through stopper that suppresses the extension of the depletion layer from the drain to the source of the LDMOSFET. Each of the plurality of p-type semiconductor regions PR can function as a contact portion of the p-type well region PB.

As shown in FIGS. 1 and 2, the n-type drain region (n-type semiconductor region) DR1 and the n-type drain region (n-type semiconductor region) DR2 are formed in the n-type drift region ND. An n-type impurity concentration of the n-type drain region DR1, and an n-type impurity concentration of the n-type drain region DR2 are higher than an n-type impurity concentration of the n-type drift region ND. The upper surface of the n-type drain region DR1, and the upper surface of the n-type drain region DR2 reach the main surface of the semiconductor substrate SB, respectively. The bottom surface of the n-type drain region DR1, and the bottom surface of the n-type drain region DR2 are shallower than the bottom surface of the n-type drift region ND, respectively.

As shown in FIG. 4, in plan view, the n-type drain region DR1 extends in the Y direction so that the distance from the side surface S1 of the gate electrode portion GE1 to the n-type drain region DR1 is substantially constant. In plan view, the n-type drain region DR2 extends in the Y direction so that the distance from the side surface S4 of the gate electrode portion GE2 to the n-type drain region DR2 is substantially constant. In plan view, the n-type drain region DR1, and the n-type drain region DR2 are spaced apart from each other in the X direction. The gate electrode portion GE1 and the gate electrode portion GE2 are arranged between the n-type drain region DR1 and the n-type drain region DR2. The array region RG is arranged between the gate electrode portion GE1 and the gate electrode portion GE2. In plan view, the gate electrode portion GE1 is arranged between the n-type drain region DR1 and the array region RG, and the gate electrode portion GE2 is arranged between the n-type drain region DR2 and the array region RG. In plan view, the distance between the n-type drain region DR1 and the gate electrode portion GE1 is greater than the distance between the array region RG and the gate electrode portion GE1. In plan view, the distance between the n-type drain region DR2 and the gate electrode portion GE2 is greater than the distance between the array region RG and the gate electrode portion GE2.

In plan view, the n-type semiconductor region EX is formed so as to surround the array region RG. As shown in FIGS. 1 to 3, the n-type semiconductor region EX is formed in the p-type well region PB so as to be in contact with the plurality of n-type source regions SR and the plurality of p-type semiconductor regions PR.

The n-type impurity concentration of the n-type semiconductor region EX is lower than the n-type impurity concentration of each of the plurality of n-type source regions SR. The upper surface of the n-type semiconductor region EX reaches the main surface of the semiconductor substrate SB. The bottom surface of the n-type semiconductor region EX is shallower than the bottom surface of each of the plurality of n-type source regions SR and also shallower than the bottom surface of each of the plurality of p-type semiconductor regions PR. The n-type semiconductor region EX can function as a Lightly Doped Drain (LDD) region. Each n-type source region SR and the adjacent n-type semiconductor region EX can function as a source region having an LDD structure.

The n-type semiconductor region EX is formed under the sidewall spacer SW1. In plan view, the n-type semiconductor region EX extends along the sidewall spacer SW1, with overlapping the sidewall spacer SW1. As shown in FIG. 4, in plan view, the n-type semiconductor region EX is formed along the inner peripheral side surface of the gate electrode GE. Therefore, the n-type semiconductor region EX extends in the Y direction along the side surface S2 of the gate electrode portion GE1, and in the X direction along the side surface S5 of the gate connection portion GEC, and also extends in the Y direction along the side surface S3 of the gate electrode portion GE2.

As shown in FIGS. 1 to 3, the n-type semiconductor region EX includes an n-type semiconductor region EX1 extending along the side surface S2 of the gate electrode portion GE1, an n-type semiconductor region EX2 extending along the side surface S5 of the gate connection portion GEC, and an n-type semiconductor region EX3 extending along the side surface S3 of the gate electrode portion GE2. The n-type semiconductor region EX is not formed under the sidewall spacer SW2.

As shown in FIGS. 1 and 5, in the X direction, one side surface of each of the plurality of n-type source regions SR and one side surface of each of the plurality of p-type semiconductor regions PR are in contact with the n-type semiconductor region EX1. In the X direction, the other side surface of each of the plurality of n-type source regions SR and the other side surface of each of the plurality of p-type semiconductor regions PR are in contact with the n-type semiconductor region EX3. As shown in FIGS. 2 and 5, in the Y direction, one side surface of the p-type semiconductor region PR1 is in contact with the n-type semiconductor region EX2. In the Y direction, the other side surface of the p-type semiconductor region PR1 is in contact with the adjacent n-type source region SR.

As shown in FIG. 5, the n-type semiconductor region EX1 is in contact with the plurality of n-type source regions SR and the plurality of p-type semiconductor regions PR, and the n-type semiconductor region EX3 is in contact with the plurality of n-type source regions SR and the plurality of p-type semiconductor regions PR. Meanwhile, the n-type semiconductor region EX2 is in contact with the p-type semiconductor region PR1 but is not in contact with any of the plurality of n-type source regions SR.

In a cross-sectional view orthogonal to the Y direction and crossing the n-type source region SR, as shown in FIG. 1, a part of the p-type well region PB and a part of the n-type drift region ND are located under the gate electrode portion GE1, and another part of the p-type well region PB and another part of the n-type drift region ND are located under the gate electrode portion GE2.

In a cross-sectional view orthogonal to the Y direction and crossing the p-type semiconductor region PR, as shown in FIG. 2, a part of the p-type well region PB and a part of the n-type drift region ND are located under the gate electrode portion GE1, and another part of the p-type well region PB and another part of the n-type drift region ND are located under the gate electrode portion GE2.

In a cross-sectional view orthogonal to the X direction and crossing the p-type semiconductor region PR1, as shown in FIG. 3, a part of the p-type well region PB and a part of the n-type drift region ND are located under the gate connection portion GEC.

A channel (n-type inversion layer) is formed in the upper part of the p-type well region PB located under the gate electrode GE. Hereinafter, the region where the channel is formed is referred to as the channel formation region. The n-type semiconductor region EX is adjacent to the channel formation region. In plan view, the n-type semiconductor region EX is interposed between the channel formation region and the array region RG. In plan view, the n-type semiconductor region EX surrounds the array region RG, and the channel formation region surrounds the n-type semiconductor region EX and the array region RG.

The gate dielectric film GF is formed of, for example, a silicon oxide film. The gate electrode GE is formed of a silicon film, specifically, a polysilicon film (doped polysilicon film). The gate electrode portion GE1, the gate connection portion GEC, and the gate electrode portion GE2 are integrally formed, but the conductivity type of the gate connection portion GEC differs from the conductivity type of each of the gate electrode portion GE1 and the gate electrode portion GE2. The gate electrode portion GE1 is formed of an n-type silicon region PSN, the gate connection portion GEC is formed of a p-type silicon region PSP, and the gate electrode portion GE2 is formed of the n-type silicon region PSN. Therefore, the gate electrode portion GE1 and the gate electrode portion GE2 each have an n-type conductivity type, and the gate connection portion GEC has a p-type conductivity type.

When a voltage higher than the threshold voltage is applied to the gate electrode GE, a channel formed of an n-type inversion layer is formed in the upper part of the p-type well region PB located under the gate electrode GE. The n-type drain region DR1, and the plurality of n-type source regions SR are conductively connected to each other through the n-type drift region ND and the channel under the gate electrode portion GE1, and the n-type drain region DR2, and the plurality of n-type source regions SR are conductively connected to each other through the n-type drift region ND and the channel under the gate electrode portion GE2.

As shown in FIGS. 4 to 6, in plan view, the n-type drift region ND is interposed between the p-type well region PB and the n-type drain region DR1, and the n-type drift region ND is interposed between the p-type well region PB and the n-type drain region DR2. Therefore, in plan view, the n-type semiconductor region EX1, the channel formation region, and the n-type drift region ND exist between the array region RG and the n-type drain region DR1, and the n-type semiconductor region EX2, the channel formation region, and the n-type drift region ND exist between the array region RG and the n-type drain region DR2.

Furthermore, a metal silicide layer (not shown) may be formed on the n-type drain region DR1, on the n-type drain region DR2, on each of the plurality of n-type source regions SR, on each of the plurality of p-type semiconductor regions PR, and on the gate electrode GE.

Next, the structure above the semiconductor substrate SB will be described.

As shown in FIGS. 1 to 3, the semiconductor device of the first embodiment further includes a plurality of plugs (contact plugs) buried in the dielectric film IL and a plurality of wirings formed over the dielectric film IL.

The dielectric film IL is formed over the main surface of the semiconductor substrate SB so as to cover the gate electrode GE. The dielectric film IL may be formed of a laminated film including, for example, a silicon nitride film and an oxide silicon film over the silicon nitride film. The upper surface of the dielectric film IL is flattened.

A plurality of contact holes (through holes) are formed in the dielectric film IL, and a plurality of conductive plugs are formed in these plurality of contact holes. These plurality of plugs include a plurality of plugs P1, a plurality of plugs P2, a plurality of plugs P3, and a plurality of plugs P4. Each of the plugs P1, the plugs P2, the plugs P3, the plugs P4 penetrates through the dielectric film IL.

Each of the plurality of plugs P1 is arranged over the n-type drain region DR1 and is electrically connected to the n-type drain region DR1. Each of the plurality of plugs P2 is arranged over the n-type drain region DR2 and is electrically connected to the n-type drain region DR2. Each of the plurality of plugs P3 is arranged over each n-type source region SR and is electrically connected to the n-type source region SR. Each of the plurality of plugs P4 is arranged over each p-type semiconductor region PR and is electrically connected to the p-type semiconductor region PR. Therefore, each plug P4 is electrically connected to the p-type well region PB via the p-type semiconductor region PR.

Furthermore, a plug is also arranged over the gate electrode GE, but the plug over the gate electrode GE is not shown in FIGS. 1 to 3.

Over the dielectric film IL, a plurality of wirings is formed. The plurality of wirings include a source wiring WS, a drain wiring WD1, and a drain wiring WD2.

The drain wiring WD1 is electrically connected to the n-type drain region DR1 via the plurality of plugs P1. A drain potential is supplied to the n-type drain region DR1 from the drain wiring WD1 via the plurality of plugs P1. The drain wiring WD2 is electrically connected to the n-type drain region DR2 via the plurality of plugs P2. A drain potential is supplied to the n-type drain region DR2 from the drain wiring WD2 via the plurality of plugs P2. The drain wiring WD1 and the drain wiring WD2 are electrically connected to each other via wirings (not shown) located above the drain wiring WD1 and the drain wiring WD2.

The source wiring WS is electrically connected to the plurality of n-type source regions SR and the plurality of p-type semiconductor regions PR, respectively, via the plurality of plugs P3 and the plurality of plugs P4. That is, the source wiring WS is electrically connected to the plurality of plugs P3 arranged over the plurality of n-type source regions SR and to the plurality of plugs P4 arranged over the plurality of p-type semiconductor regions PR. Therefore, the source potential is supplied to the plurality of n-type source regions SR from the source wiring WS via the plurality of plugs P3, and to the plurality of p-type semiconductor regions PR from the source wiring WS via the plurality of plugs P4. Since the bottom surfaces of the plurality of p-type semiconductor regions PR are covered with the p-type well region PB, the source potential supplied to the plurality of p-type semiconductor regions PR is supplied from the plurality of p-type semiconductor regions PR to the p-type well region PB.

A gate wiring electrically connected to the gate electrode GE via a plug is formed over the dielectric film IL, but in FIGS. 1 to 3, the gate wiring is not shown.

Illustration and description of structures located above the dielectric film IL, drain wiring WD1, drain wiring WD2, and source wiring WS are omitted.

The LDMOSFET 1 may be configured by connecting a plurality of unit LDMOSFETs in parallel. In the case of FIGS. 1 to 6, the LDMOSFET 1 has a configuration in which two-unit LDMOSFETs sharing a source are connected in parallel. The number of units LDMOSFETS to be connected in parallel can be set as needed.

### Manufacturing Step of Semiconductor Device

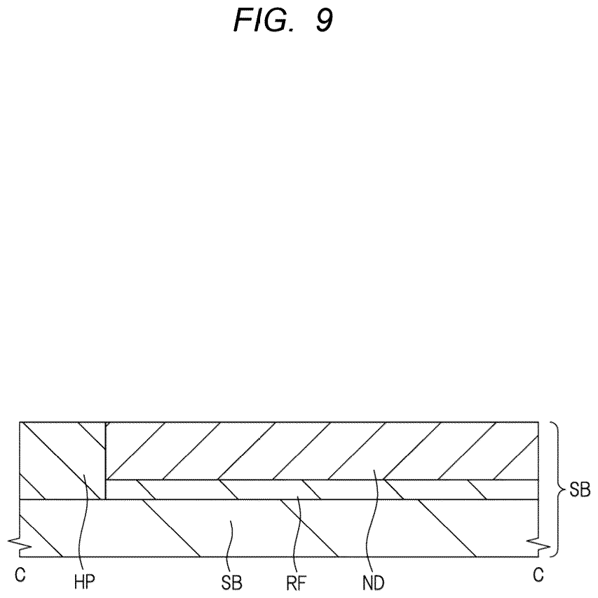

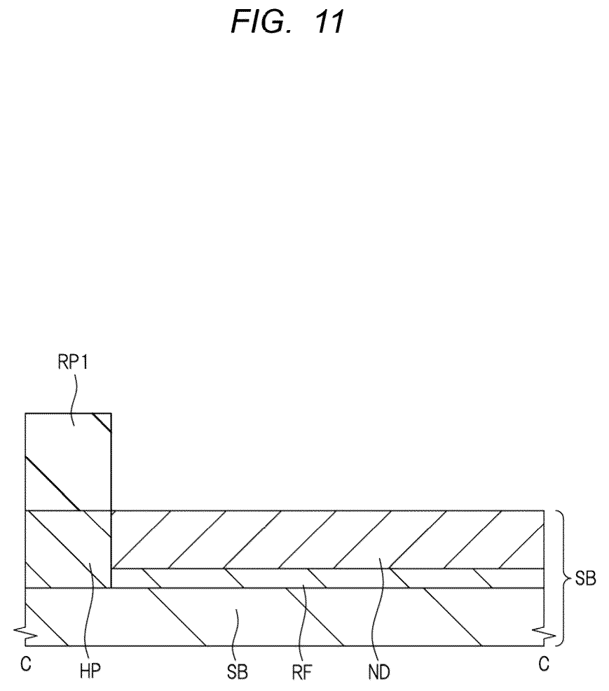

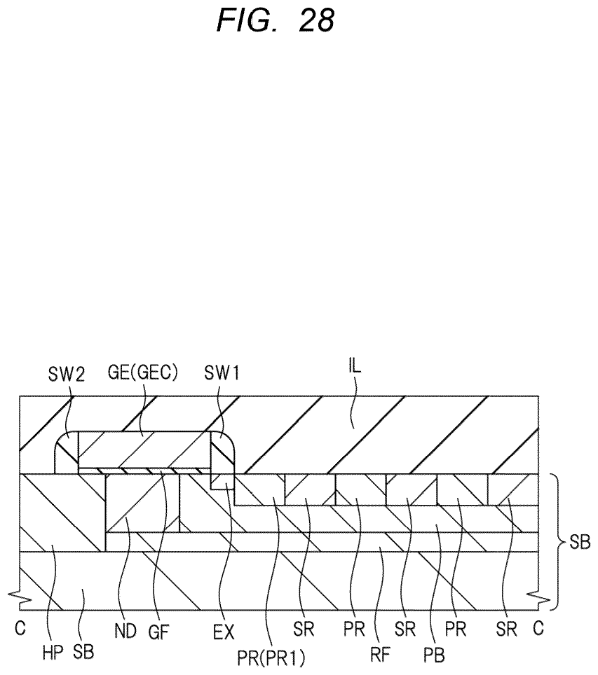

FIGS. 9, 10, 12, 15, 17, 19, 21, 23, 25, and 27 are cross-sectional views corresponding to the above FIG. 1, and shows cross-sectional views along the line A-A of FIGS. 4 to 6. FIGS. 11, 13, 16, 18, 20, 22, 24, 26, and 28 are cross-sectional views corresponding to the above FIG. 3, and shows cross-sectional views along the line C-C of FIGS. 4 to 6.

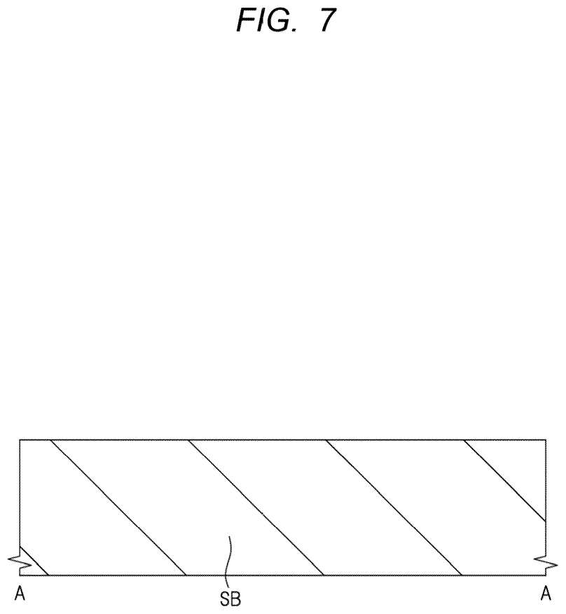

As shown in FIG. 7, the semiconductor substrate SB is prepared. The semiconductor substrate SB may, for example, be made of p-type single-crystal silicon. An epitaxial wafer may be used as the semiconductor substrate SB. The semiconductor substrate SB may have an n-type buried layer formed therein.

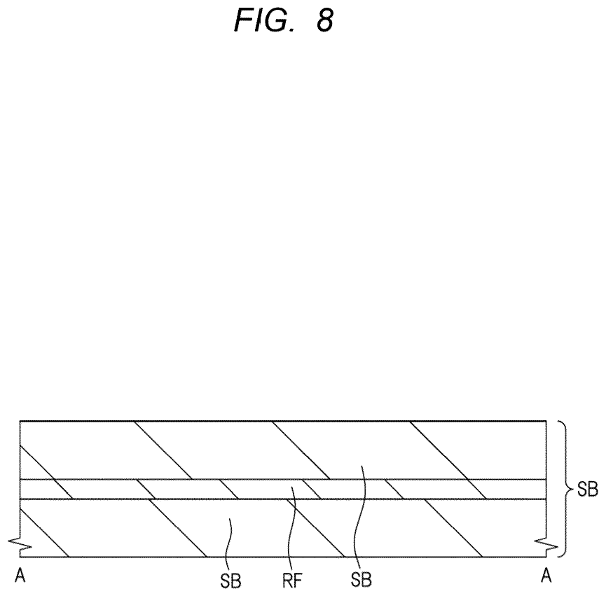

Next, as shown in FIGS. 8 and 9, the p-type resurf region RF and the p-type semiconductor region HP are formed in the semiconductor substrate SB using ion implantation or the like. In the first embodiment, the p-type resurf region RF and the p-type semiconductor region HP are formed, but either or both of the p-type RESURF region RF and the p-type semiconductor region HP may not be formed.

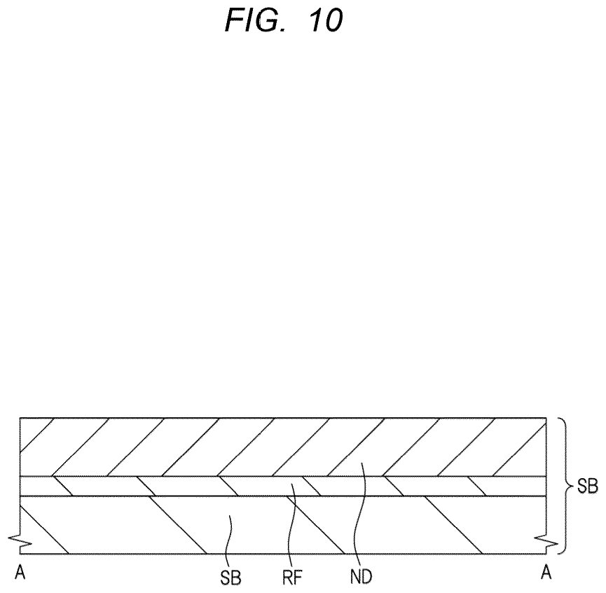

Next, as shown in FIGS. 10 and 11, a photoresist pattern (mask layer) RP1 is formed over the main surface of the semiconductor substrate SB using photolithography technique. Thereafter, n-type impurities are implanted into the semiconductor substrate SB using the photoresist pattern RP1 as an ion implantation blocking mask to form the n-type drift region ND in the semiconductor substrate SB. After the ion implantation, the photoresist pattern RP1 is removed. The n-type drift region ND is formed to a predetermined depth from the main surface of the semiconductor substrate SB. In plan view, the n-type drift region ND includes the region where the p-type well region PB will be formed later.

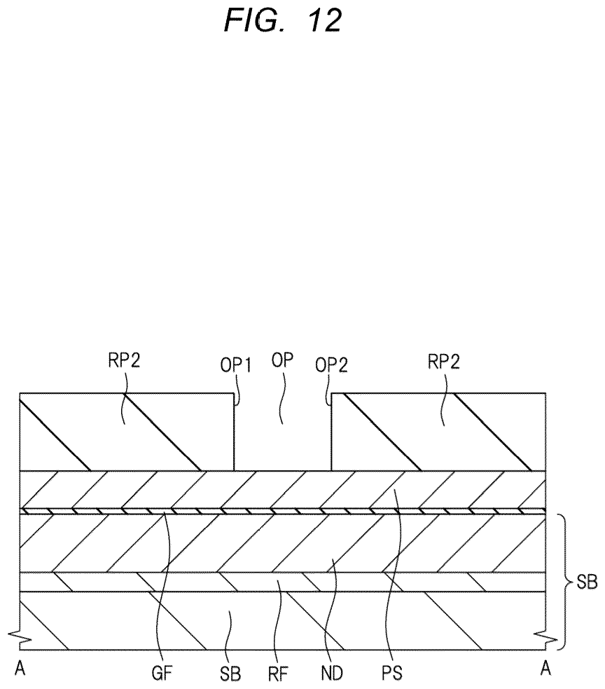

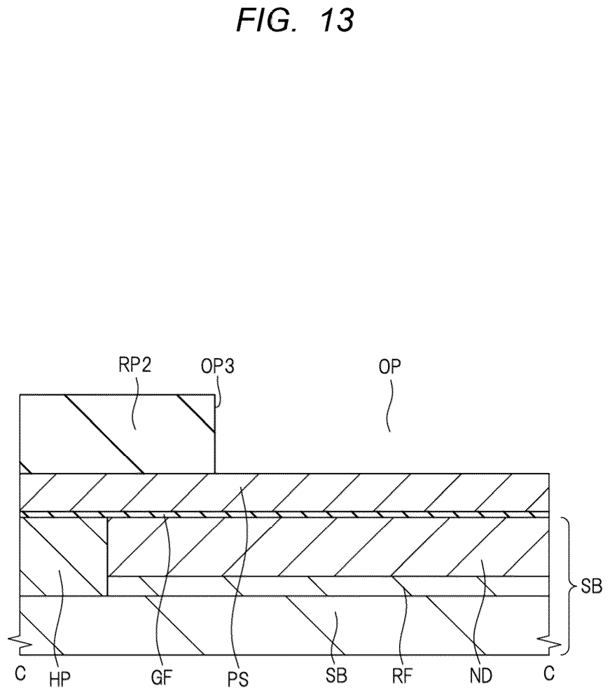

Next, as shown in FIGS. 12 and 13, A silicon film PS is formed over the main surface of the semiconductor substrate SB via the gate dielectric film GF. The gate dielectric film GF is formed of, for example, a silicon oxide film. The silicon film PS specifically is formed of a polysilicon film.

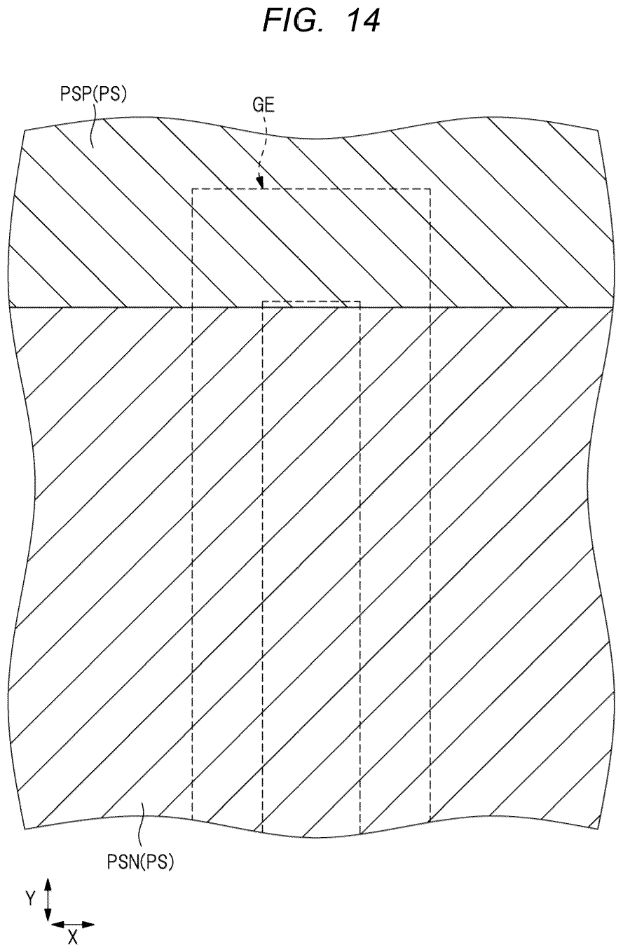

Next, as shown in FIG. 14, the n-type silicon region PSN and the p-type silicon region PSP are formed in the silicon film PS using ion implantation or the like.

Although FIG. 14 is plan view, in FIG. 14, different hatchings indicating different directions are applied to the n-type silicon region PSN and the p-type silicon region PSP. In FIG. 14, the position of the gate electrode GE to be formed later is indicated by a dotted line. As can be seen from FIG. 14 and the above-mentioned FIG. 4, the regions where the gate electrode portion GE1 and the gate electrode portion GE2 of the gate electrode GE are formed are included in the n-type silicon region PSN, and the region where the gate connection portion GEC of the gate electrode GE is formed is included in the p-type silicon region PSP.

Next, as shown in FIGS. 12 and 13, a photoresist pattern (mask layer) RP2 is formed over the silicon film PS using photolithography technique. The photoresist pattern RP2 has an opening portion OP. The opening portion OP has a side surface OP1, a side surface OP2, a side surface OP3. The side surface OP1 and the side surface OP2 are opposite each other and parallel in the Y direction. The side surface OP3 intersects with the side surface OP1 and the side surface OP2 and is parallel in the X direction. In FIGS. 12 and 13, the side surface facing the side surface OP3 is not shown.

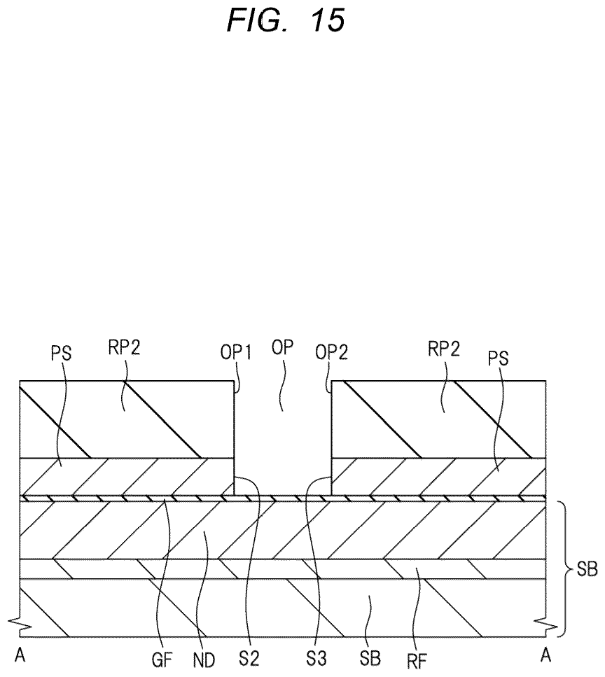

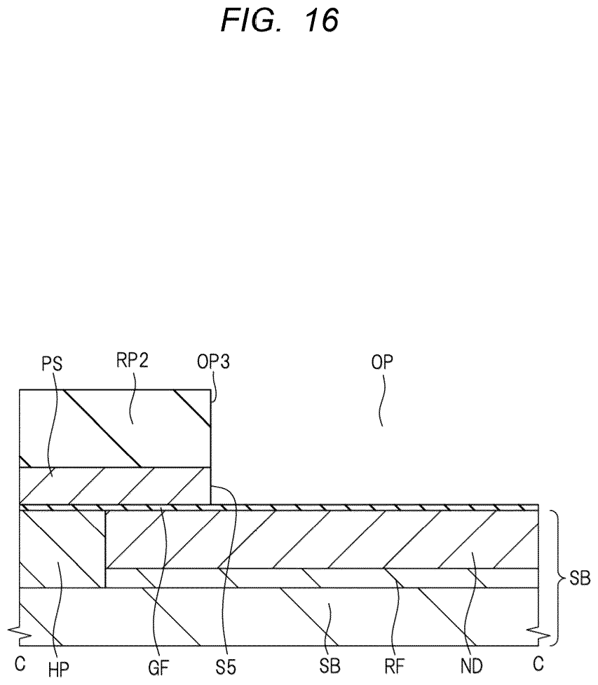

Next, as shown in FIGS. 15 and 16, by etching the silicon film PS using the photoresist pattern RP2 as an etching mask, an opening portion aligned with the opening portion OP of the photoresist pattern RP2 is formed in the silicon film PS. Thus, the side surface S2, the side surface S3, the side surface S5 are formed as the side surfaces of the opening portion of the silicon film PS. The side surface S2 of the silicon film PS aligns with the side surface OP1 of the opening portion OP, the side surface S3 of the silicon film PS aligns with the side surface OP2 of the opening portion OP, and the side surface S5 of the silicon film PS aligns with the side surface OP3 of the opening portion OP. Hereinafter, the entire combination of the opening portion OP of the photoresist pattern RP2 and the opening portion of the silicon film PS is referred to as the opening portion OP.

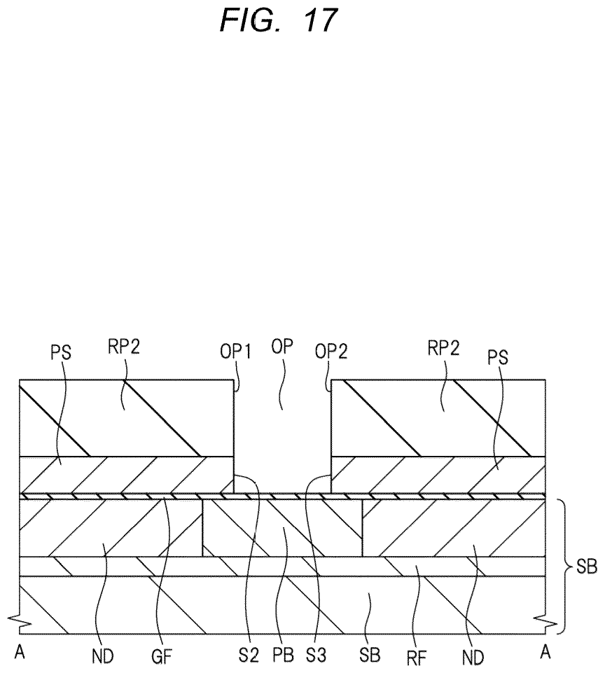

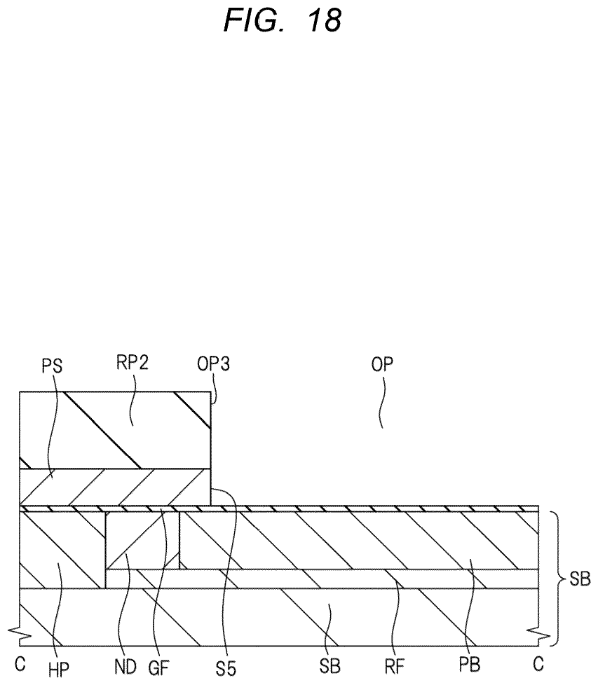

Next, as shown in FIGS. 17 and 18, by implanting p-type impurities into the semiconductor substrate SB by ion implantation using the silicon film PS and the photoresist pattern RP2 over the silicon film PS as an ion implantation blocking mask, the p-type well region PB is formed in the semiconductor substrate SB. The p-type well region PB is formed by implanting p-type impurities into a part of the n-type drift region ND. Therefore, the effective p-type impurity concentration of the p-type well region PB is defined by the difference between the concentration of n-type impurities contained in the n-type drift region ND and the concentration of p-type impurities implanted to form the p-type well region PB. The p-type impurity concentration of the p-type well region PB is higher than the p-type impurity concentration of the p-type semiconductor substrate SB. The p-type well region PB is formed over a predetermined depth from the main surface of the semiconductor substrate SB.

For the ion implantation to form the p-type well region PB, oblique ion implantation is used. In the case of oblique ion implantation, the direction of ion implantation is inclined relative to the normal direction of the main surface of the semiconductor substrate SB. By using oblique ion implantation to form the p-type well region PB, the p-type well region PB is formed at a position overlapping the opening portion OP in plan view, and a part of the p-type well region PB is formed under the silicon film PS. Therefore, in plan view, the p-type well region PB is formed to include the opening portion OP. The planar dimension (planar area) of the p-type well region PB is larger than the planar dimension (planar area) of the opening portion OP.

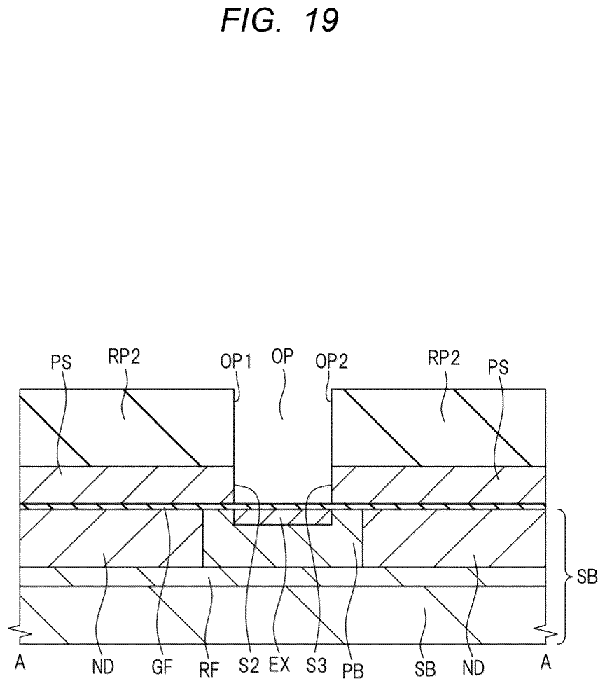

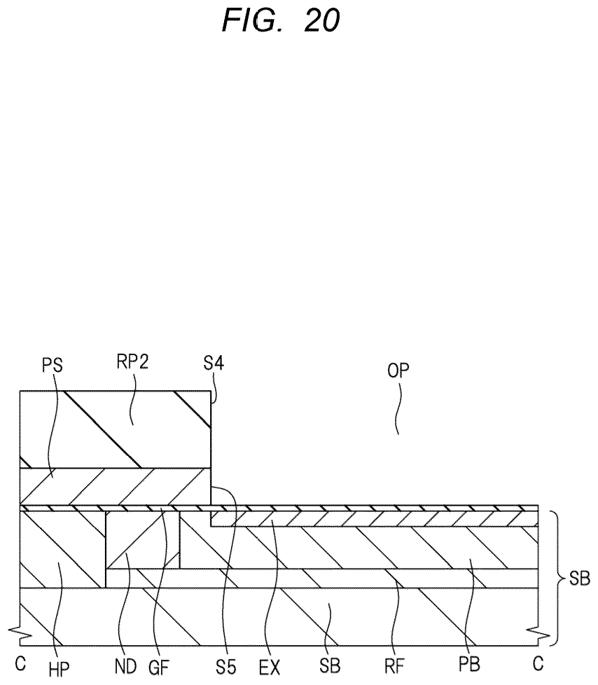

Next, as shown in FIGS. 19 and 20, by implanting n-type impurities into the semiconductor substrate SB by ion implantation using the silicon film PS and the photoresist pattern RP2 over the silicon film PS as an ion implantation blocking mask, the n-type semiconductor region EX is formed in the semiconductor substrate SB. The n-type semiconductor region EX is formed over a predetermined depth from the main surface of the semiconductor substrate SB. The depth of the bottom surface of the n-type semiconductor region EX is shallower than the depth of the p-type well region PB.

For the ion implantation to form the n-type semiconductor region EX, vertical ion implantation is used. In the case of vertical ion implantation, the direction of ion implantation is parallel to the normal direction of the main surface of the semiconductor substrate SB. By using vertical ion implantation to form the n-type semiconductor region EX, the n-type semiconductor region EX is formed self-aligned with the opening portion OP. Therefore, in plan view, the n-type semiconductor region EX is formed to overlap the opening portion OP, and the outer peripheral side surface of the n-type semiconductor region EX substantially corresponds to the side surface of the opening portion OP. Consequently, in plan view, the outer peripheral side surface of the n-type semiconductor region EX substantially corresponds to the side surface S2, the side surface S3, the side surface S5 of the silicon film PS. In plan view, the n-type semiconductor region EX is included by the p-type well region PB.

In the first embodiment, the p-type well region PB is formed after forming the n-type semiconductor region EX. It may also be possible to form the p-type well region PB after forming the n-type semiconductor region EX.

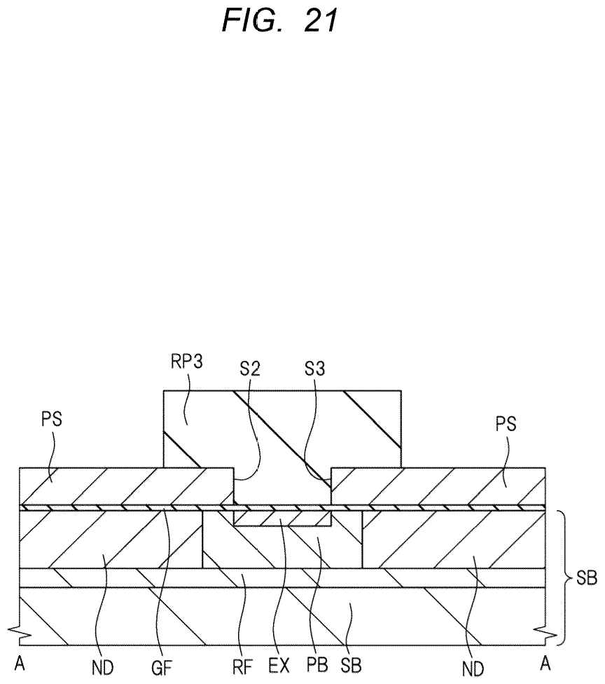

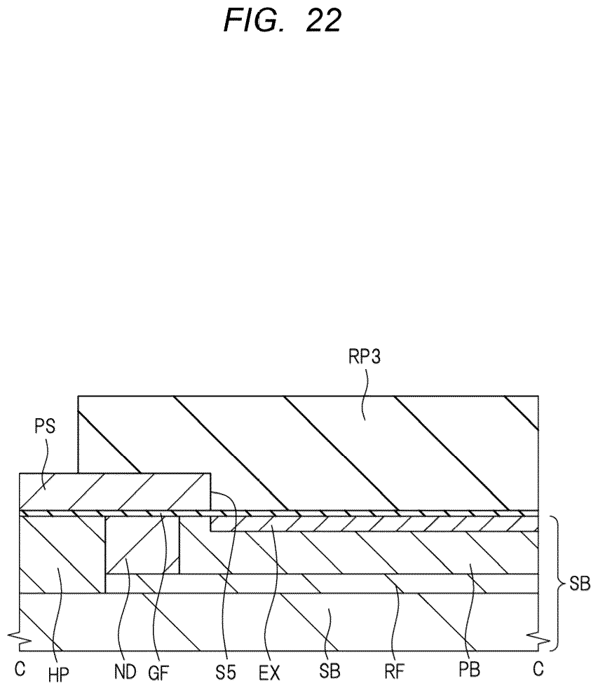

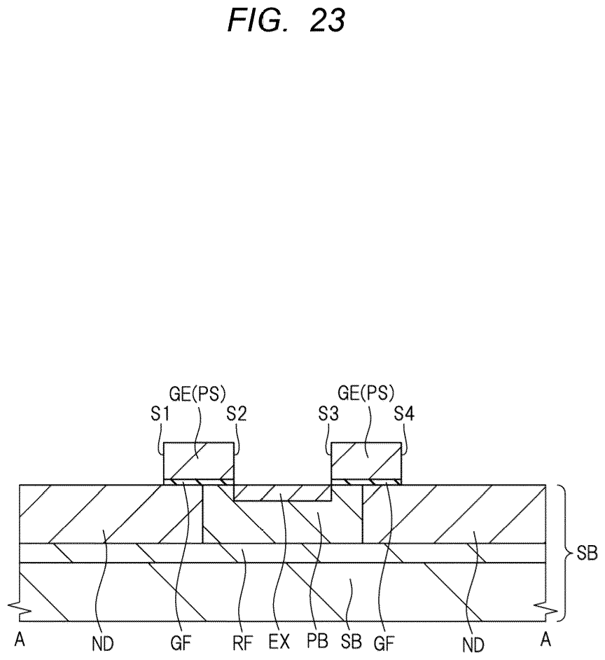

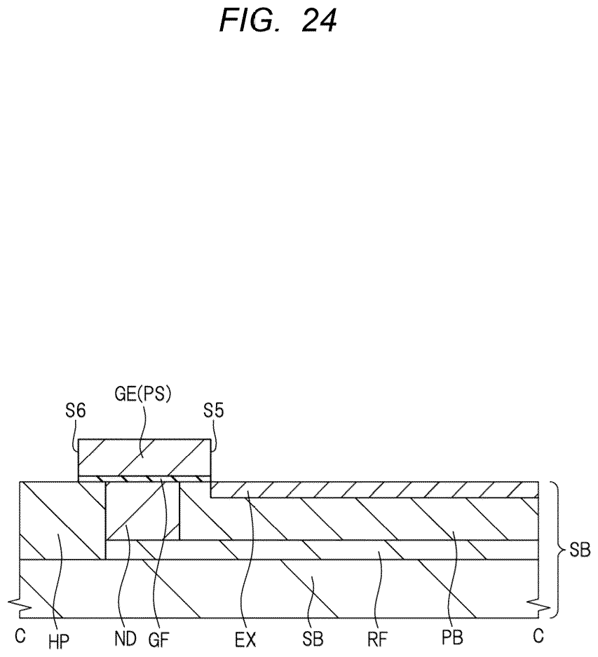

Subsequently, after removing the photoresist pattern RP2, as shown in FIGS. 21 and 22, a photoresist pattern (mask layer) RP3 is formed using photolithography techniques to fill the opening portion (OP) in the silicon film PS and to cover a part of the silicon film PS. The opening portion (OP) of the silicon film PS is covered by the photoresist pattern RP2. Thereafter, the silicon film PS is patterned by etching the silicon film PS using the photoresist pattern RP3 as an etching mask. Then, the photoresist pattern RP3 is removed. As shown in FIGS. 23 and 24, the gate electrode GE is formed by the patterned silicon film PS.

The outer peripheral side surfaces of the gate electrode GE are formed by etching using the photoresist pattern RP3. Therefore, the side surface S1, the side surface S4, the side surface S6 are formed by etching using the photoresist pattern RP3. The inner peripheral side surfaces of the gate electrode GE are formed by the side surfaces of the opening portion OP. Therefore, the side surface S2, the side surface S3, the side surface S5 are formed by the side surfaces of the opening portion OP. The gate electrode portion GE1 and the gate electrode portion GE2 of the gate electrode GE are formed by the n-type silicon region PSN (refer to FIG. 14), and the gate connection portion GEC of the gate electrode GE is formed by the p-type silicon region PSP (refer to FIG. 14).

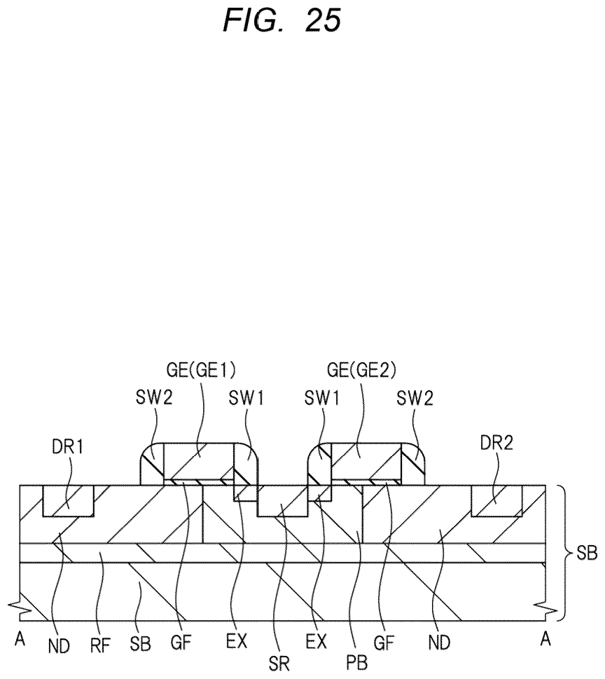

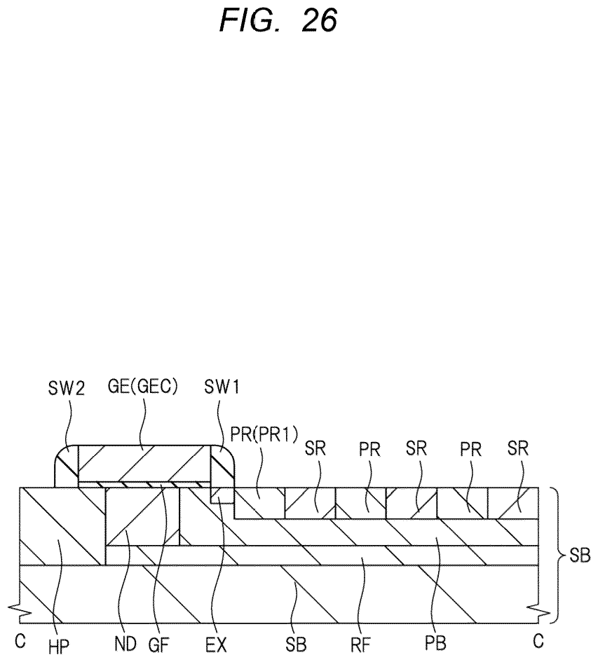

Next, as shown in FIGS. 25 and 26, the sidewall spacer SW1 is formed on the inner peripheral side surface of the gate electrode GE, and the sidewall spacer SW2 is formed on the outer peripheral side surface of the gate electrode GE. The sidewall spacer SW1 and the sidewall spacer SW2 can be formed in the same step. For example, after forming the dielectric film over the semiconductor substrate SB so as to cover the gate electrode GE, the sidewall spacer SW1 and the sidewall spacer SW2 can be formed by etching back the dielectric film.

Next, as shown in FIGS. 25 and 26, the n-type drain region DR1, the n-type drain region DR2 and the plurality of n-type source regions SR are formed in the semiconductor substrate SB using a method such as ion implantation.

The n-type drain region DR1 and the n-type drain region DR2 are formed in the n-type drift region ND. The n-type impurity concentration of the n-type drain region DR1 and the n-type impurity concentration of the n-type drain region DR2 are higher than the n-type impurity concentration of the n-type drift region ND.

The plurality of n-type source regions SR is formed in the p-type well region PB. The n-type impurity concentration of each of the plurality of n-type source regions SR is higher than the n-type impurity concentration of the n-type semiconductor region EX. The depth of the bottom surface of each of the plurality of n-type source regions SR is deeper than the depth of the bottom surface of the n-type semiconductor region EX.

For forming the plurality of n-type source regions SR, vertical ion implantation is used. Therefore, the plurality of n-type source regions SR is formed self-aligned to the sidewall spacer SW1. Consequently, the n-type semiconductor region EX remains under the sidewall spacer SW1 adjacent to the plurality of n-type source regions SR. The n-type drain region DR and the plurality of n-type source regions SR can be formed by the same ion implantation step, which can reduce the number of manufacturing steps, but they can also be formed by separate ion implantation steps.

Next, as shown in FIGS. 25 and 26, the plurality of p-type semiconductor regions PR are formed in the semiconductor substrate SB using a method such as ion implantation.

The plurality of p-type semiconductor regions PR are formed in the p-type well region PB. The impurity concentration of each of the plurality of p-type semiconductor regions PR is higher than the impurity concentration of the p-type well region PB. The bottom surface of each of the plurality of p-type semiconductor regions PR is deeper than the bottom surface of the p-type well region PB.

In the first embodiment, after forming the n-type drain region DR1, the n-type drain region DR2, and the plurality of n-type source regions SR, the plurality of p-type semiconductor regions PR are formed. It is also possible to form the n-type drain region DR1, the n-type drain region DR2, and the plurality of n-type source regions SR after forming the plurality of p-type semiconductor regions PR.

After forming the plurality of n-type source regions SR, the n-type drain region DR1, the n-type drain region DR2, and the plurality of p-type semiconductor regions PR, a metal silicide layer (not shown) may be formed on each of the n-type drain region DR1, on the n-type drain region DR2, on the plurality of n-type source regions SR, on the plurality of p-type semiconductor regions PR, and on the upper surface of the gate electrode GE. The metal silicide layer is formed using Salicide (Self Aligned Silicide) technique.

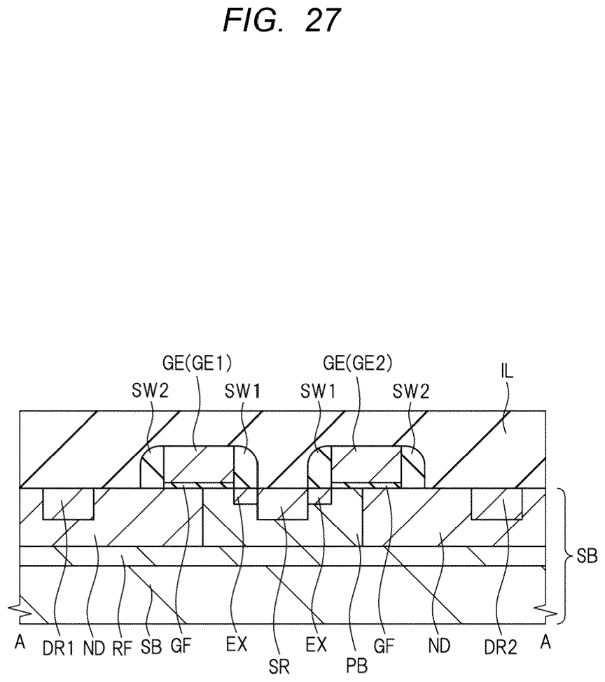

Next, as shown in FIGS. 26 and 27, the dielectric film IL is formed over the main surface of the semiconductor substrate SB so as to cover the gate electrode GE using a method such as Chemical Vapor Deposition (CVD). After forming the dielectric film IL, the upper surface of the dielectric film IL may be polished and planarized using a method such as CMP.

Next, as shown in FIGS. 1 to 3, a plurality of contact holes penetrating through the dielectric film IL are formed by etching the dielectric film IL using a photoresist pattern (not shown) formed over the dielectric film IL as an etching mask. Subsequently, a plurality of conductive plugs are formed in the plurality of contact holes, respectively. The plurality of plugs include the plurality of plugs P1, the plurality of plugs P2, the plurality of plugs P3, and the plurality of plugs P4.

Next, as shown in FIGS. 1 to 3, a plurality of wirings is formed over the dielectric film IL. The plurality of wirings include the drain wiring WD1, the drain wiring WD2, and the source wiring WS.

The illustration and description of the step of forming further upper dielectric films and wirings are omitted.

In the first embodiment, by performing ion implantation of n-type impurities and p-type impurities into the silicon film PS, the n-type silicon region PSN and the p-type silicon region PSP are formed in the silicon film PS, and thereafter, the silicon film PS is processed to form the gate electrode GE. The silicon film PS is processed to form the gate electrode GE, and thereafter, n-type impurities may be ion-implanted into the inside of the gate electrode portion GE1 and the gate electrode portion GE2, and p-type impurities may be ion-implanted into the inside of the gate connection portion GEC. In that case, it is preferable to implant n-type impurities into the inside of the gate electrode portion GE1 and the gate electrode portion GE2 during the ion implantation step for forming the plurality of n-type source regions SR, the n-type drain region DR1, and the n-type drain region DR2. Also, it is preferable to implant p-type impurities into the gate connection portion GEC during the ion implantation process for forming the plurality of p-type semiconductor regions PR.

### History of Examined Example

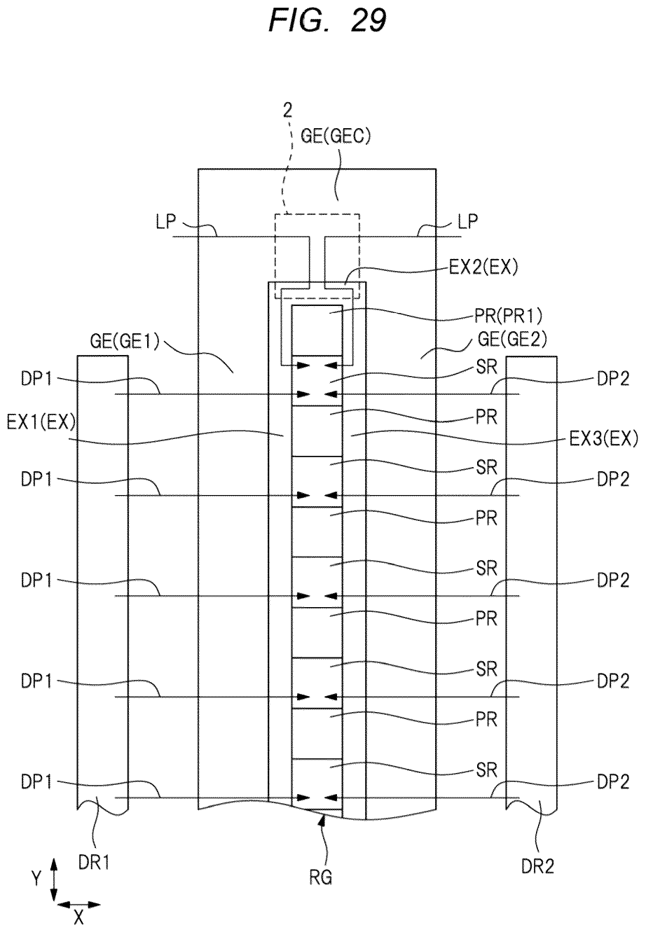

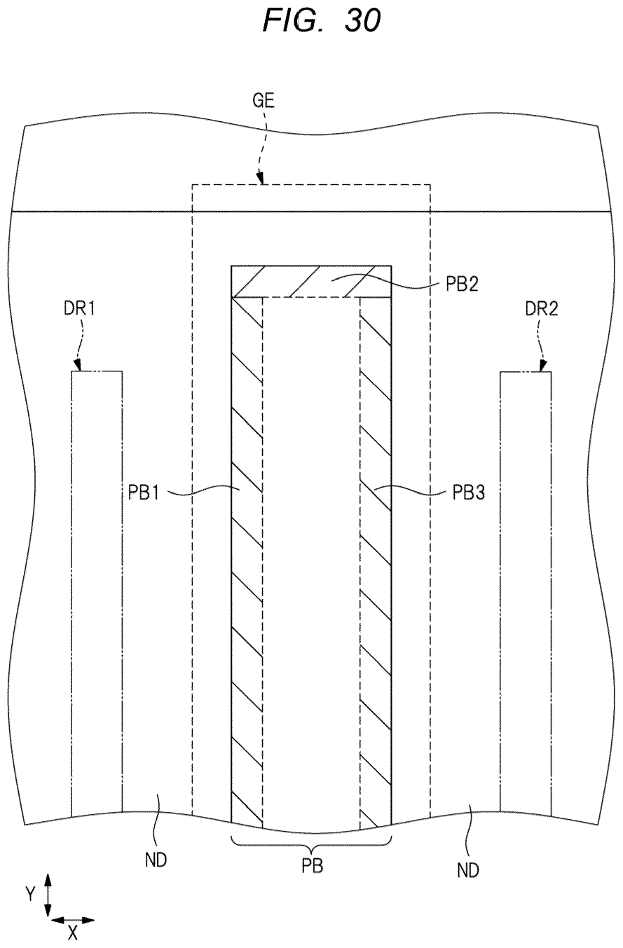

FIGS. 29 and 30 show planar regions corresponding to FIGS. 4 to 6 above.

In the semiconductor device of the examined example studied by the inventors, the entire gate electrode GE is of n-type conductivity. Therefore, in the examined example, both the gate electrode portion GEL and the gate electrode portion GE2 and the gate connection portion GEC are formed of an n-type silicon film into which n-type impurities have been introduced, and they have n-type conductivity.

When a voltage higher than the threshold voltage of the LDMOSFET 1 is applied to the gate electrode GE, a channel formed of an n-type inversion layer is formed in the upper part of the p-type well region PB located under the gate electrode portion GE1 and the gate electrode portion GE2. As a result, the n-type drain region DR1 and the plurality of n-type source regions SR are conductively connected to each other via the n-type drift region ND and the channel under the gate electrode portion GE1. The n-type drain region DR2 and the plurality of n-type source regions SR are conductively connected to each other via the n-type drift region ND and the channel under the gate electrode portion GE1. Thus, as shown in FIG. 29, current flows in the X direction from the n-type drain region DR1 to the plurality of n-type source regions SR, passing under the gate electrode portion GE1, and as shown in FIG. 29, current flows in the X direction from the n-type drain region DR2 to the plurality of n-type source regions SR, passing under the gate electrode portion GE2.

However, due to the formation of the gate connection portion GEC and the n-type semiconductor region EX2, a parasitic MOSFET 2 is formed over the main surface of the semiconductor substrate SB. In FIG. 29, the region where the parasitic MOSFET 2 is formed is indicated by a dotted line. The gate connection portion GEC functions as the gate electrode of the parasitic MOSFET 2, the n-type semiconductor region EX2 functions as the source region of the parasitic MOSFET 2, and the n-type drift region ND under the gate connection portion GEC functions as the drain region of the parasitic MOSFET 2.

When a voltage higher than the threshold voltage of the parasitic MOSFET 2 is applied to the gate connection portion GEC, a channel formed of an n-type inversion layer is formed in the upper part of the p-type well region PB located under the gate connection portion GEC, and the parasitic MOSFET 2 is set to on-state.

When the parasitic MOSFET 2 is turned on, in the cross-section shown in FIG. 3, the n-type semiconductor region EX2 and the n-type drift region ND under the gate connection portion GEC are electrically connected to each other via the channel under the gate connection portion GEC. As a result, as shown in a current path LP in FIGS. 3 and 29, the current flows from the n-type drain region DR1 and the n-type drain region DR2 to the n-type semiconductor region EX2 via the n-type drift region ND under the gate connection portion GEC and the channel, and further flows to the n-type source region SR via the n-type semiconductor region EX1 and the n-type semiconductor region EX3.

The current path LP is not the intended current path as an LDMOSFET but a leakage current path flowing via the parasitic MOSFET 2. The flow of current from the n-type drain region DR1 and the n-type drain region DR2 to the n-type source region SR via the parasitic MOSFET 2, as in the current path LP, can cause leakage current and is therefore undesirable. For this reason, it is desirable to suppress or prevent the flow of current from the n-type drain region DR1 and the n-type drain region DR2 to the n-type source region SR via the parasitic MOSFET 2.

The p-type impurity concentration in the p-type well region PB under the gate connection portion GEC tends to be lower than the p-type impurity concentration in the p-type well region PB under each of the gate electrode portion GE1 and the gate electrode portion GE2. FIG. 29 shows a p-type region PB1, a p-type region PB2, and a p-type region PB3 with hatching. The p-type region PB1 corresponds to the p-type well region PB located under the gate electrode portion GE1. The p-type region PB2 corresponds to the p-type well region PB located under the gate connection portion GEC. The p-type region PB3 corresponds to the p-type well region PB located under the gate electrode portion GE2. The p-type impurity concentration in the p-type region PB2 tends to be lower than the p-type impurity concentration in each of the p-type region PB1, and the p-type region PB3.

In the examined example, reflecting the lower p-type impurity concentration in the p-type region PB2 compared to each of the p-type region PB1 and the p-type region PB3, the threshold voltage of the parasitic MOSFET 2 becomes lower than the threshold voltage of the LDMOSFET 1. This is because, in the case of an n-type MOSFET, the lower the p-type impurity concentration in the p-type well region under the gate electrode, the lower the tendency for the threshold voltage. The threshold voltage of the LDMOSFET 1 corresponds to the threshold voltage based on a current path DP1 and a current path DP2. The threshold voltage of the parasitic MOSFET 2 corresponds to the threshold voltage based on the current path LP.

If the threshold voltage of the parasitic MOSFET 2 is lower than the threshold voltage of the LDMOSFET 1, when a voltage is applied to the gate electrode GE, the parasitic MOSFET 2 operates before the LDMOSFET 1. This is undesirable as it can lead to an increase in leakage current or cause punch-through.

The reason why the p-type impurity concentration in the p-type well region PB (p-type region PB2) under the gate connection portion GEC is lower than the p-type impurity concentration in the p-type well regions PB (p-type regions PB1, PB3) under each of the gate electrode portion GE1 and the gate electrode portion GE2 is as follows.

The p-type well region PB is formed by oblique ion implantation. During oblique ion implantation, p-type impurity ions are reflected by the side surface of the opening portion OP, and the reflected p-type impurity ions are also implanted into the semiconductor substrate SB, contributing to the formation of the p-type well region PB. In the p-type well region PB under the gate electrode portion GE1, p-type impurity ions reflected by the side surface OP2 (refer to FIG. 17) of the opening portion OP during oblique ion implantation are also implanted. In the p-type well region PB under the gate electrode portion GE2, p-type impurity ions reflected by the side surface OP1 (refer to FIG. 17) of the opening portion OP during oblique ion implantation are also implanted. However, in the p-type well region PB under the gate connection portion GEC, almost no p-type impurity ions reflected by any side surface of the opening portion OP during oblique ion implantation are implanted. This is due to the dimension (length) in the Y direction of the opening portion OP being larger than the dimension (length) in the X direction of the opening portion OP. The distance between the side surface OP3 of the opening portion OP and the side surface facing the side surface OP3 is greater than the distance between the side surface OP1 and the side surface OP2 of the opening portion OP, hence, p-type impurity ions reflected by the side surface of the opening portion OP hardly affect the p-type impurity concentration in the p-type region PB2. As a result, the p-type impurity concentration in the p-type well region PB (p-type region PB2) under the gate connection portion GEC is lower than the p-type impurity concentration in the p-type well regions PB (p-type region PB1, p-type region PB3) under the gate electrode portion GE1 and the gate electrode portion GE2, respectively.

### Features and Effects of First Embodiment

In the first embodiment, the conductivity type of the gate electrode GE is not uniform. The gate electrode portion GE1 and the gate electrode portion GE2 each have an n-type conductivity, and the gate connection portion GEC has a p-type conductivity. Specifically, the gate electrode portion GEL is formed of the n-type silicon region PSN, the gate connection portion GEC is formed of the p-type silicon region PSP, and the gate electrode portion GE2 is formed of the n-type silicon region PSN. As a result, it is possible to suppress or prevent the effect of the parasitic MOSFET 2, thereby improving the performance of the semiconductor device including the LDMOSFET 1.

Comparing the use of an n-type silicon gate with a p-type silicon gate as the gate electrode of an n-channel MOSFET, if the structure other than the gate electrode is the same, the threshold voltage of the n-channel MOSFET using the p-type silicon gate is higher than that of the n-channel MOSFET using the n-type silicon gate. Therefore, it is common to use an n-type silicon gate as the gate electrode of an n-channel MOSFET. This is because lowering the threshold voltage of the n-channel MOSFET allows for a lower operating voltage of the n-channel MOSFET.

However, it is desirable to suppress the operation of the parasitic MOSFET 2 during the operation of the LDMOSFET 1. Therefore, in the first embodiment, the gate electrode portion GE1 and the gate electrode portion GE2 each have an n-type conductivity, and the gate connection portion GEC has a p-type conductivity. This allows maintaining the threshold voltage of the LDMOSFET 1, in which the gate electrode portion GE1 and the gate electrode portion GE2 function as a gate electrode, at a predetermined voltage, while increasing the threshold voltage of the parasitic MOSFET 2, in which the gate connection portion GEC functions as a gate electrode. Specifically, when comparing the examined example with the first embodiment, the threshold voltage of the LDMOSFET 1 in the first embodiment is the same as that in the examined example, and the threshold voltage of the parasitic MOSFET 2 in the first embodiment is higher than that in the examined example. As a result, in the first embodiment, it is possible to suppress or prevent the effect of the parasitic MOSFET 2, thereby improving the performance of the semiconductor device including the LDMOSFET 1. For example, it is possible to suppress or prevent the operation of the parasitic MOSFET 2 before the operation of the LDMOSFET 1 when a voltage is applied to the gate electrode GE. As a result, it is possible to suppress the leakage current. Or it is possible to prevent punch-through caused by the parasitic MOSFET 2.

Contrary to the first embodiment, it is conceivable to form the n-type semiconductor region EX such that the n-type semiconductor region EX2 is not formed along the side surface S5 of the gate connection portion GEC. Since the n-type semiconductor region EX2 functions as the source region of the parasitic MOSFET 2, if the n-type semiconductor region EX2 is not formed along the side surface S5 of the gate connection portion GEC, the parasitic MOSFET 2 will not be formed.

However, in order to form the n-type semiconductor region EX such that the n-type semiconductor region EX2 is not formed, it is necessary to use a different ion implantation blocking mask (photoresist pattern) than the ion implantation blocking mask (the aforementioned photoresist pattern RP2) used in the ion implantation step for forming the p-type well region PB during the ion implantation step for forming the n-type semiconductor region EX. This leads to an increase in the number of manufacturing steps and the cost of manufacturing the semiconductor device.

In contrast, in the case of the first embodiment, a common ion implantation blocking mask (the aforementioned photoresist pattern RP2) can be used in both the ion implantation step for forming the n-type semiconductor region EX and the ion implantation step for forming the p-type well region PB. Therefore, it is possible to suppress the number of manufacturing steps and the cost of manufacturing the semiconductor device.

When a common ion implantation blocking mask (the aforementioned photoresist pattern RP2) is used in the ion implantation step for forming the n-type semiconductor region EX and the ion implantation step for forming the p-type well region PB, the n-type semiconductor region EX includes the n-type semiconductor region EX2 along the side surface S5 of the gate connection portion GEC. If the n-type semiconductor region EX includes the n-type semiconductor region EX2, the parasitic MOSFET 2 is formed. In the case of the first embodiment, although the n-type semiconductor region EX2 is formed along the side surface S5 of the gate connection portion GEC, as described above, it is possible to increase the threshold voltage of the parasitic MOSFET 2. Therefore, the formation of the parasitic MOSFET 2 by the n-type semiconductor region EX2 along the side surface S5 of the gate connection portion GEC can be tolerated. As a result, it is possible to achieve both improvement in the performance of the semiconductor device and suppression of the manufacturing cost of the semiconductor device.

The technical idea of the first embodiment is to lower the threshold voltage of the LDMOSFET 1 in the current path DP1 and the current path DP2, and to increase the threshold voltage of the parasitic MOSFET 2 in the current path LP.

In the current path DP1 and the current path DP2, to lower the threshold voltage of the LDMOSFET 1, the gate electrode portion GE1 and the gate electrode portion GE2 over the channel formation region are configured by the n-type silicon region PSN. Therefore, in a cross-sectional view orthogonal to the Y direction, the gate electrode portion GE1 and the gate electrode portion GE2 over the p-type well region PB are configured by the n-type silicon region PSN in any cross-section cutting across any of the plurality of n-type source regions SR. This allows for the lowering of the threshold voltage of the LDMOSFET 1 in the current path DP1 and the current path DP2.

In the current path DP1 and the current path DP2, to increase the threshold voltage of the parasitic MOSFET 2, the gate connection portion GEC over the channel formation region is configured by the p-type silicon region PSP. Therefore, in a cross-sectional view orthogonal to the X direction, the gate connection portion GEC over the p-type well region PB is configured by the p-type silicon region PSP at any position of the side surface S5. This allows the threshold voltage of the parasitic MOSFET 2 in the current path DP1 and the current path DP2 to be increased.

### Second Embodiment

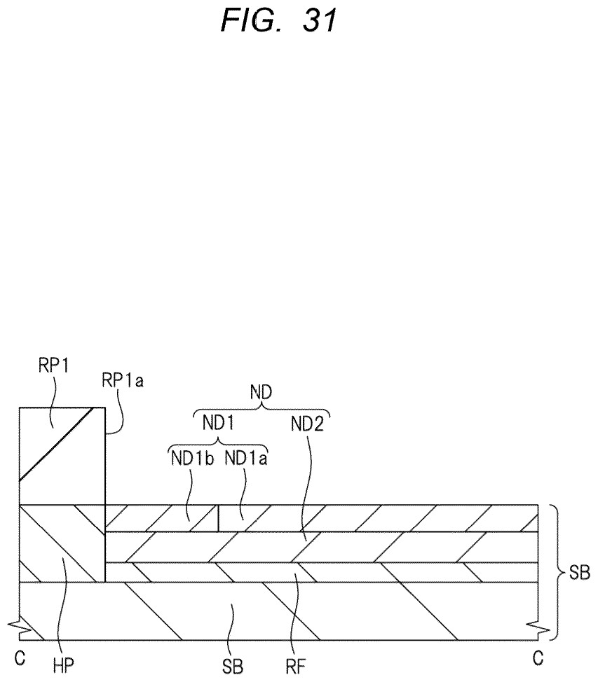

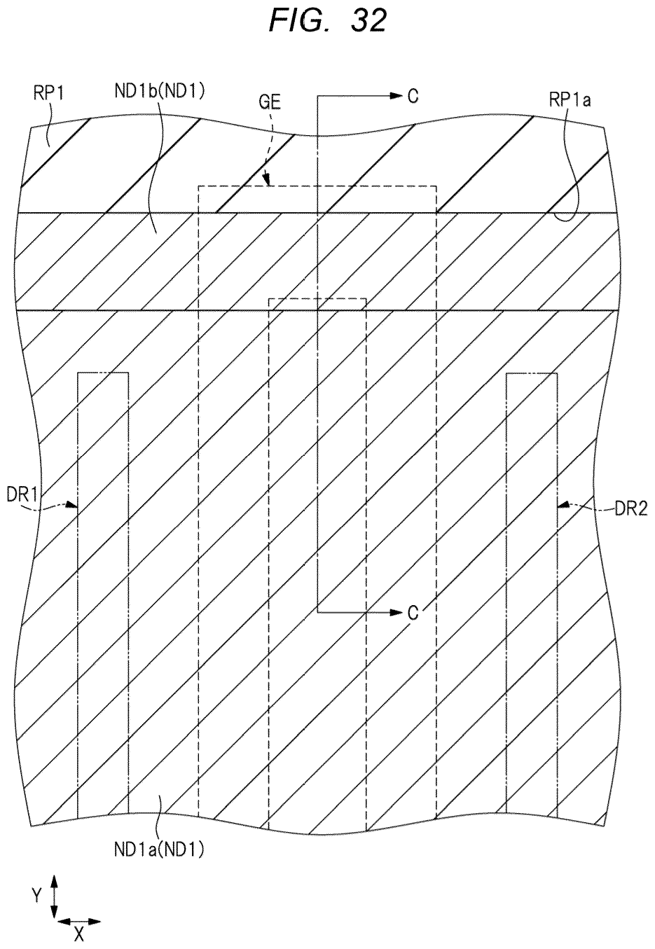

FIG. 31 is a cross-sectional view corresponding to FIG. 11 above, showing a cross-sectional view along the line C-C of FIGS. 4 to 6. FIG. 32 shows the position of the gate electrode GE to be formed later in dashed lines, and the positions of the n-type drain region DR1 and the n-type drain region DR2 to be formed later in dash-dotted lines.

A difference between the second embodiment and the first embodiment is the step of forming the n-type drift region ND.

In the first embodiment, the n-type drift region ND is formed by vertical ion implantation without using oblique ion implantation. Therefore, in the first embodiment, the n-type impurity concentration in the surface portion of the n-type drift region ND shown in FIGS. 10 and 11 is substantially constant regardless of the planar position.

In the second embodiment, as shown in FIG. 31, after forming the photoresist pattern RP1 over the main surface of the semiconductor substrate SB using photolithography technique, n-type impurities are implanted into the semiconductor substrate SB using the photoresist pattern RP1 as a mask, thereby forming an n-type semiconductor region ND1 in the semiconductor substrate SB. The n-type semiconductor region ND1 is formed using oblique ion implantation. Next, by implanting n-type impurities into the semiconductor substrate SB using the photoresist pattern RP1 as a mask, an n-type semiconductor region ND2 is formed in the semiconductor substrate SB. The n-type semiconductor region ND2 is formed using vertical ion implantation. Thereafter, the photoresist pattern RP1 is removed.

The ion implantation energy for forming the n-type semiconductor region ND1 is lower than the ion implantation energy for forming the n-type semiconductor region ND2. Therefore, in the semiconductor substrate SB, the n-type semiconductor region ND2 is formed under the n-type semiconductor region ND1. The n-type drift region ND is formed by the n-type semiconductor region ND1 and the n-type semiconductor region ND2 located under the n-type semiconductor region ND1. The n-type semiconductor region ND1 configures the upper part of the n-type drift region ND, and the n-type semiconductor region ND2 configures the lower part of the n-type drift region ND.

When oblique ion implantation is performed using the photoresist pattern RP1 as a mask, due to the shielding effect of the photoresist pattern RP1, the density of impurities implanted into the semiconductor substrate SB becomes locally lower near the side surface of the photoresist pattern RP1. Therefore, when the n-type semiconductor region ND1 is formed by oblique ion implantation, the n-type impurity concentration in the n-type semiconductor region ND1 becomes locally lower near the side surface of the photoresist pattern RP1. As a result, the n-type impurity concentration in an n-type semiconductor region ND1b shown in FIGS. 31 and 32 is lower than the n-type impurity concentration in an n-type semiconductor region ND1a. The n-type impurity concentration in the surface portion of the n-type semiconductor region ND1a is substantially constant regardless of the planar position.

The n-type semiconductor region ND1b is a part of the n-type semiconductor region ND1, and the n-type semiconductor region ND1a is another part of the n-type semiconductor region ND1. The n-type semiconductor region ND1b and the n-type semiconductor region ND1a are adjacent to each other in the Y direction. A side surface RP1a of the photoresist pattern RP1 is parallel to the X direction. In plan view, the side surface RP1a of the photoresist pattern RP1 crosses the region where the gate connection portion GEC is formed. In plan view, the side surface RP1a of the photoresist pattern RP1 and the n-type semiconductor region ND1a are spaced apart from each other in the X direction, with the n-type semiconductor region ND1b existing between the side surface RP1a of the photoresist pattern RP1 and the n-type semiconductor region ND1a. In plan view, it is preferable to set the implantation angle of oblique ion implantation so that the region where the gate connection portion GEC is formed is located in the n-type semiconductor region ND2. The formation step of the n-type semiconductor region ND1 may be performed after the formation step of the n-type semiconductor region ND2.

For steps after the formation step of the n-type drift region ND, the present second embodiment is similar to the first embodiment.

In the case of the present second embodiment, it is possible to further increase the threshold voltage of the parasitic MOSFET 2 compared to the first embodiment. As a result, the performance of the semiconductor device can be further improved.

The reason why it is possible to further increase the threshold voltage of the parasitic MOSFET 2 in the present second embodiment will be explained.

After forming the n-type drift region ND, the p-type well region PB is formed. In plan view, the p-type well region PB is formed in the n-type drift region ND. Therefore, in the p-type well region PB, there exist n-type impurities implanted by ion implantation for forming the n-type drift region ND and p-type impurities implanted by ion implantation for forming the p-type well region PB. Due to the density of the p-type impurities in the p-type well region PB being greater than the density of the n-type impurities in the p-type well region PB, the effective conductivity type of the p-type well region PB becomes p-type. Therefore, the difference between the density of the p-type impurities and the density of the n-type impurities defines the effective p-type impurity concentration of the p-type well region PB.

In the present second embodiment, the n-type impurity concentration of the n-type semiconductor region ND1b is lower than the n-type impurity concentration of the n-type semiconductor region ND1a. The gate connection portion GEC, which is formed later, is located in the n-type semiconductor region ND1b in plan view. Utilizing this, it is possible to increase the effective p-type impurity concentration of the upper part of the p-well region PB(PB2) located under the gate connection portion GEC. As a result, the effective p-type impurity concentration of the channel formation region of the parasitic MOSFET 2 can be increased.

On the other hand, in the case of the first embodiment, the n-type impurity concentration of the n-type semiconductor region ND1b is the same as the n-type impurity concentration of the n-type semiconductor region ND1a. Therefore, in the case of the second embodiment, compared to the first embodiment, it is possible to increase the effective p-type impurity concentration in the upper part of the p-type well region PB(PB2) located under the gate connection portion GEC. Consequently, it is possible to increase the threshold voltage of the parasitic MOSFET 2 in the second embodiment compared to the first embodiment.

A channel is formed in the upper part of the p-type well region PB located under the gate electrode GE. Therefore, the n-type impurity concentration of the n-type semiconductor region ND1 affects the impurity concentration of the channel formation region, but the n-type impurity concentration of the n-type semiconductor region ND2 hardly affects the impurity concentration of the channel formation region. Therefore, the n-type semiconductor region ND2 can be formed by vertical ion implantation. As a result, the n-type impurity concentration of the n-type semiconductor region ND2 is almost constant regardless of the planar position. Therefore, it is possible to stabilize the characteristics of the semiconductor device.

On the other hand, in the case of the first embodiment, since the n-type drift region ND can be formed by vertical ion implantation without using oblique ion implantation, it is possible to simplify the step of forming the n-type drift region ND. This allows, for example, to shorten the manufacturing time of the semiconductor device. Alternatively, it is possible to reduce the manufacturing cost of the semiconductor device.

If the n-type drift region ND formation step of the second embodiment is applied when the gate connection portion GEC is formed of p-type silicon as in the first embodiment, it is possible to further increase the threshold voltage of the parasitic MOSFET 2.

Unlike the first embodiment, when the gate electrode portion GE1, the gate electrode portion GE2, and the gate connection portion GEC are formed of n-type silicon, it is also possible to apply the n-type drift region ND formation step of the second embodiment. In that case, compared to not applying the n-type drift region ND formation step of the second embodiment, it is possible to increase the threshold voltage of the parasitic MOSFET 2. This allows suppressing the influence of the parasitic MOSFET 2, thereby improving the performance of semiconductor devices including LDMOSFET.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a semiconductor substrate;
a gate electrode formed over a main surface of the semiconductor substrate via a gate dielectric film;
a drift region of a first conductivity type formed in the semiconductor substrate;
a well region of a second conductivity type opposite the first conductivity type formed in the semiconductor substrate;
a first drain region of the first conductivity type formed in the drift region, the first drain region having a higher impurity concentration than the drift region;
a second drain region of the first conductivity type formed in the drift region, the second drain region having a higher impurity concentration than the drift region;
a first semiconductor region of the first conductivity type formed in the well region; and
at least one source region of the first conductivity type formed in the well region, the at least one source region having a higher impurity concentration than the first semiconductor region,
wherein the gate electrode comprises:
a first gate electrode portion of the first conductivity type extending in a first direction;
a second gate electrode portion of the first conductivity type extending in the first direction, the second gate electrode portion being spaced apart from the first gate electrode portion in a second direction orthogonal to the first direction; and
a gate connection portion of the second conductivity type connecting the first gate electrode portion and the second gate electrode portion,
wherein in plan view, the first drain region and the second drain region are spaced apart from each other in the second direction,
wherein in plan view, the first gate electrode portion and the second gate electrode portion are arranged between the first drain region and the second drain region,
wherein in plan view, the at least one source region is arranged between the first gate electrode portion and the second gate electrode portion,
wherein in plan view, the well region is surrounded by the drift region,
wherein in plan view, a part of the first gate electrode portion, a part of the second gate electrode portion, and a part of the gate connection portion overlap the well region,
wherein in plan view, another part of the first gate electrode portion, another part of the second gate electrode portion, and another part of the gate connection portion overlap the drift region,
wherein the first gate electrode portion has a first side surface facing the second gate electrode portion,
wherein the second gate electrode portion has a second side surface facing the first gate electrode portion,
wherein the gate connection portion has a third side surface intersecting the first side surface and the second side surface,
wherein in plan view, the first semiconductor region is formed along the first side surface of the first gate electrode portion, along the third side surface of the gate connection portion, and along the second side surface of the second gate electrode portion.

2. The semiconductor device according to claim 1,
wherein the first gate electrode portion is made of silicon of the first conductivity type,
wherein the second gate electrode portion is made of silicon of the first conductivity type, and
wherein the gate connection portion is made of silicon of the second conductivity type.

3. The semiconductor device according to claim 2,
wherein the first conductivity type is n-type, and
wherein the second conductivity type is p-type.

4. The semiconductor device according to claim 2,
wherein the first gate electrode portion, the gate connection portion, and the second gate electrode portion are integrally formed.

5. The semiconductor device according to claim 1,
wherein the at least one source region is in contact with the first semiconductor region along the first side surface of the first gate electrode portion and the first semiconductor region along the second side surface of the second gate electrode portion.

6. The semiconductor device according to claim 1, comprising:
a plurality of second semiconductor regions of the second conductivity type,
wherein the at least one source region comprises a plurality of source regions, and
wherein in plan view, the plurality of source regions and the plurality of second semiconductor regions are alternately arranged in the first direction between the first gate electrode portion and the second gate electrode portion.

7. The semiconductor device according to claim 1,
wherein the first semiconductor region along the third side surface of the gate connection portion is in contact with any one of the plurality of second semiconductor regions.

8. The semiconductor device according to claim 1,
wherein an impurity concentration of the well region under the gate connection portion is lower than an impurity concentration of the well region under the first gate electrode portion and is lower than an impurity concentration of the well region under the second gate electrode portion.

9. The semiconductor device according to claim 1,
wherein each of the first side surface of the first gate electrode portion and the second side surface of the second gate electrode portion are parallel to the first direction, and
wherein the third side surface of the gate connection portion is parallel to the second direction.

10. A method of manufacturing a semiconductor device, the method comprising:
(a) preparing a semiconductor substrate;
(b) forming a drift region of a first conductivity type in the semiconductor substrate;
(c) forming a silicon film over a main surface of the semiconductor substrate via a gate dielectric film;
(d) etching the silicon film to form an opening portion in the silicon film;
(e) after the (d), forming a well region of a second conductivity type opposite the first conductivity type in the semiconductor substrate so as to include the opening portion in plan view;
(f) after the (d), forming a first semiconductor region of the first conductivity type in the semiconductor substrate so as to overlap the opening portion in plan view;
(g) after the (e) and the (f), etching the silicon film to form a gate electrode;
(h) forming a sidewall spacer on a side surface of the gate electrode; and
(i) after the (h), forming a first drain region of the first conductivity type having a higher impurity concentration than the drift region and a second drain region of the first conductivity type having a higher impurity concentration than the drift region in the drift region, and forming at least one source region of the first conductivity type having a higher impurity concentration than the first semiconductor region in the well region,
wherein the gate electrode comprises:
a first gate electrode portion of the first conductivity type extending in a first direction;
a second gate electrode portion of the first conductivity type extending in the first direction, the second gate electrode portion being spaced apart from the first gate electrode portion in a second direction orthogonal to the first direction; and
a gate connection portion of the second conductivity type connecting the first gate electrode portion and the second gate electrode portion,
wherein in plan view, the first drain region and the second drain region are spaced apart from each other in the second direction,
wherein in plan view, the first gate electrode portion and the second gate electrode portion are located between the first drain region and the second drain region,
wherein in plan view, the at least one source region is located between the first gate electrode portion and the second gate electrode portion,
wherein in plan view, a part of the first gate electrode portion, a part of the second gate electrode portion, and a part of the gate connection portion overlap the well region,
wherein in plan view, another part of the first gate electrode portion, another part of the second gate electrode portion, and another part of the gate connection portion overlap the drift region,
wherein the first gate electrode portion has a first side surface facing the second gate electrode portion,
wherein the second gate electrode portion has a second side surface facing the first gate electrode portion,
wherein the gate connection portion has a third side surface intersecting the first side surface and the second side surface, and
wherein the first side surface, the second side surface, and the third side surface configure a part of a side surface of the opening portion.

11. The method according to claim 10,
wherein in the (e), the well region is formed by oblique ion implantation, and
wherein in the (f), the first semiconductor region is formed by vertical ion implantation.

12. The method according to claim 11, comprising:
(d1) after the (c) and before the (d), forming a first mask layer over the silicon film; and
(h1) after the (e) and the (f) and before the (g), removing the first mask layer,
wherein in the (d), the silicon film is etched using the first mask layer as an etching mask to form an opening portion in the silicon film,
wherein in the (e), the well region is formed by implanting impurities of the second conductivity type into the semiconductor substrate using oblique ion implantation, using the silicon film and the first mask layer as an ion implantation blocking mask, and
wherein in the (f), the first semiconductor region is formed by implanting impurities of the first conductivity type into the semiconductor substrate using vertical ion implantation, using the silicon film and the first mask layer as the ion implantation blocking mask.

13. The method according to claim 12, comprising:
(h2) after the (h1) and before the (g), forming a second mask layer over the main surface of the semiconductor substrate so as to cover the opening portion and partially cover the silicon film,
wherein in the (g), the gate electrode is formed by etching the silicon film using the second mask layer as an etching mask.

14. The method according to claim 10, comprising:
(k) after the (h), forming a plurality of second semiconductor regions of the second conductivity type having a higher impurity concentration than the well region in the well region,
wherein the at least one source region comprises a plurality of source regions,
wherein in plan view, the plurality of source regions and the plurality of second semiconductor regions are alternately arranged in the first direction between the first gate electrode portion and the second gate electrode portion.

15. The method according to claim 14,
wherein in the (k), the first semiconductor region along the third side surface of the gate connection portion is in contact with any one of the plurality of second semiconductor regions.

16. The method according to claim 10,
wherein the (b) comprises:
(b1) forming a third mask layer over the main surface of the semiconductor substrate;
(b2) after the (b1), forming the drift region in the semiconductor substrate using ion implantation; and
(b3) after the (b2), removing the third mask layer.

17. The method according to claim 16,
wherein the (b2) comprises:
(b4) implanting impurities of the second conductivity type into the semiconductor substrate using oblique ion implantation, using the third mask layer as an ion implantation blocking mask; and
(b5) implanting impurities of the second conductivity type into the semiconductor substrate using vertical ion implantation, using the third mask layer as the ion implantation blocking mask,
wherein an implantation energy of oblique ion implantation in the (b4) is lower than an implantation energy of vertical ion implantation in the (b5).
